(19) United States
(12) Patent Application Publication
(10) Pub. No.: US 2023/0333165 A1
(43) Pub. Date: Oct. 19, 2023

(54) STORAGE BATTERY INTERNAL STATE ESTIMATION DEVICE AND STORAGE BATTERY INTERNAL STATE ESTIMATION METHOD

(71) Applicant: Mitsubishi Electric Corporation, Tokyo (JP)

(72) Inventor: Tomoki TAKEGAMI, Tokyo (JP)

(73) Assignee: Mitsubishi Electric Corporation, Tokyo (JP)

(21) Appl. No.: 18/008,187

(22) PCT Filed: Aug. 4, 2020
(86) PCT No.: PCT/JP2020/029841

§ 371 Date: Dec. 5, 2022

(51) Int. Cl. G01R 31/367; G01R 31/3842; G01R 31/392

(52) U.S. Cl. CPC G01R 31/367; G01R 31/3842; G01R 31/392

(57) ABSTRACT

A storage battery internal state estimation device includes a data generation unit and an estimation unit. The data generation unit generates time-series data for estimation from time-series data of a current value and a voltage value acquired from a storage battery. The estimation unit estimates a model function of the storage battery on the basis of the time-series data for estimation. The time-series data for estimation includes Z_{Dj}-th (j=1,..., N_{D}) order differential voltage curves, the number of which is “N_{D}” that is an integer of one or more, where “Z_{Dj}” is a positive real number, and Z_{Dk}≠1 for at least one “k”.

### FIELD

The present disclosure relates to a storage battery internal state estimation device and a storage battery internal state estimation method for estimating an internal state of a storage battery.

### BACKGROUND

In the aim of reducing the environmental load, electric vehicles such as an electric vehicle (EV), a hybrid electric vehicle (HEV), and a plug-in hybrid vehicle (PHV) have been put into practical use. Also, electric aircraft or the like has been under development. Furthermore, stationary power storage systems for utilizing renewable energy have become widespread.

These pieces of machinery use storage batteries such as lithium ion batteries. The storage batteries are known to deteriorate with use and have reduced performance. In order to recognize the performance and time of replacement of these storage batteries and to predict the life of the storage batteries, deterioration diagnosis needs to be performed on the storage batteries.

As a method of deterioration diagnosis for a storage battery, Patent Literature 1 below discloses a technique using a differential voltage curve. An implementation procedure of this technique is as follows. First, a differential voltage curve obtained from electrical characteristics of a positive electrode material and a negative electrode material of a storage battery is acquired in advance. Next, a fitting function that fits the differential voltage curve and parameters of the fitting function are obtained by calculation. Finally, the deterioration diagnosis is performed on the basis of fluctuations of the parameters of the fitting function calculated from a peak position, a peak height, a peak width, and the like of the differential voltage curve obtained from a measured value of the storage battery in use.

### CITATION LIST

### Patent Literature

Patent Literature 1: Japanese Patent No. 6123844

### SUMMARY

### Technical Problem

In a conventional technique, a positive electrode voltage curve and a negative electrode voltage curve obtained from the electrical characteristics of the positive electrode material and the negative electrode material of the storage battery acquired in advance are often implicitly assumed that the shape of an electrode charging rate-voltage curve with the horizontal axis representing the electrode charging rate does not change. Then, on the basis of this assumption, an electrode capacity-voltage curve with the horizontal axis representing an electrode charge amount acquired in advance for each of the positive electrode and the negative electrode is reduced or shifted to the right and left, whereby a capacity-voltage curve of the deteriorated storage battery cell is modeled while different deterioration modes are quantitatively estimated. However, in reality, a phenomenon is observed in which the shape of the electrode capacity-voltage curve changes and a local fluctuation in the voltage becomes gradual. That is, the shape of the electrode capacity-voltage curve often has a gentler peak when viewed in the differential voltage curve. This phenomenon is considered to occur because, as the storage battery deteriorates, a degree of deterioration varies among a large number of particles forming the electrode, or a conductive path between each particle and a current collector is likely to be interrupted to cause a variation in the charging rate of each particle at the time of charging and discharging. Therefore, instead of using characteristic information of the storage battery acquired in advance as it is, there is a demand for an accurate deterioration diagnosis technique based on modeling of a storage battery voltage curve that can reflect a change in the shape of the voltage curve or the differential voltage curve according to the deterioration.

The present disclosure has been made in view of the above, and an object of the present disclosure is to provide a storage battery internal state estimation device capable of performing accurate deterioration diagnosis even in the absence of characteristic information on a storage battery to be diagnosed.

### Solution to Problem

In order to solve the above problem and achieve the object, a storage battery internal state estimation device according to the present disclosure includes a data generation unit and an estimation unit. The data generation unit generates time-series data for estimation from time-series data of a current value and a voltage value acquired from a storage battery. The estimation unit estimates a model function of the storage battery on the basis of the time-series data for estimation. The time-series data for estimation includes Z_{Dj}-th (j=1,..., N_{D}) order differential voltage curves, the number of which is “N_{D}” that is an integer of one or more, where “Z_{Dj}” is a positive real number, and Z_{Dk}≠1 for at least one “k”.

### Advantageous Effects of Invention

The storage battery internal state estimation device according to the present disclosure has an effect of enabling accurate deterioration diagnosis even in the absence of the characteristic information on the storage battery to be diagnosed.

### BRIEF DESCRIPTION OF DRAWINGS

FIG. 1 is a diagram illustrating an example of a configuration of a storage battery deterioration diagnosis system including a storage battery internal state estimation device according to a first embodiment.

FIG. 2 is a block diagram illustrating an example of a hardware configuration of the storage battery internal state estimation device according to the first embodiment.

FIG. 3 is a set of graphs plotting curves from a second-order differential to a second-order integral of a logistic function used in a proposed technique of the first embodiment.

FIG. 4 is a set of graphs plotting curves from a second-order differential to a second-order integral when the value of a scale σ is changed in the logistic function used in the proposed technique of the first embodiment.

FIG. 5 is a set of graphs plotting curves of even-order integral functions from a second-order integral to a tenth-order integral when the value of the scale σ is changed in the logistic function used in the proposed technique of the first embodiment.

FIG. 6 is a set of graphs plotting curves for each skew parameter v when the value of the skew parameter v is gradually varied for a skew peak function generated using density functions of six different types of distributions by the proposed technique of the first embodiment.

FIG. 7 is a characteristic chart illustrating an example of a potential curve of a positive electrode and a differential potential curve of the positive electrode in a general lithium ion battery including an Ni-Mn-Co (NMC)-based positive electrode and a graphite negative electrode.

FIG. 8 is a characteristic chart illustrating an example of a potential curve of the negative electrode and a differential potential curve of the negative electrode in the same lithium ion battery as that illustrated in FIG. 7.

FIG. 9 is a set of graphs illustrating an example of separation and estimation by high-order differential performed using the proposed technique of the first embodiment.

FIG. 10 is a set of graphs for explaining deterioration modes reflected in a voltage function of a storage battery cell used in the description of the proposed technique of the first embodiment.

FIG. 11 is a flowchart illustrating an example of a processing procedure by a storage battery internal state estimation method according to the first embodiment.

FIG. 12 is a diagram illustrating an example of a configuration of a storage battery deterioration diagnosis system including a storage battery internal state estimation device according to a second embodiment.

### DESCRIPTION OF EMBODIMENTS

Hereinafter, a storage battery internal state estimation device and a storage battery internal state estimation method according to embodiments of the present disclosure will be described in detail with reference to the drawings. Note that in the drawings, the same reference numerals indicate the same or equivalent parts.

### First Embodiment

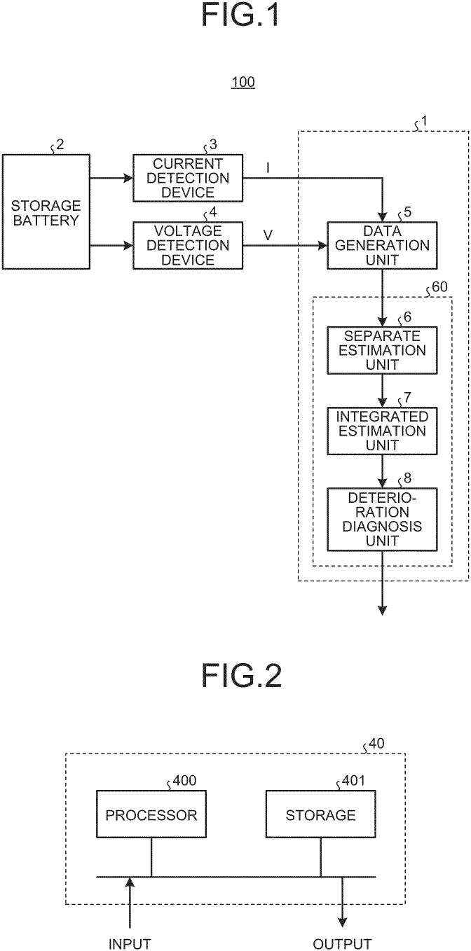

FIG. 1 is a diagram illustrating an example of a configuration of a storage battery deterioration diagnosis system 100 including a storage battery internal state estimation device 1 according to a first embodiment. As illustrated in FIG. 1, the storage battery deterioration diagnosis system 100 includes the storage battery internal state estimation device 1, a storage battery 2, a current detection device 3, and a voltage detection device 4. The storage battery internal state estimation device 1 according to the first embodiment is a device that estimates an internal state of the storage battery 2. The estimation of the internal state is a concept including estimation of a deterioration state of the storage battery 2 and also including estimation of a degree and progress of deterioration of the storage battery 2, a degree of reduction in the capacity of the storage battery 2, a deterioration parameter serving as an index of the degree of deterioration of the storage battery 2, and the like.

An example of a lithium ion battery to be diagnosed is a lithium ion battery using an NMC-based material for a positive electrode and graphite for a negative electrode. Note that the storage battery 2 to be diagnosed may include a general storage battery with a positive electrode and a negative electrode and capable of charging and discharging, in addition to a lithium ion battery made of another material system. Besides the lithium ion battery, the storage battery 2 to be diagnosed may be a lead-acid battery, a nickel-hydrogen storage battery, an all-solid-state storage battery, or the like. Also, besides the storage battery of a single cell, the storage battery 2 to be diagnosed may be a storage battery module in which a plurality of cells is connected in series or a storage battery module in which a plurality of cells is connected in parallel. The storage battery to be diagnosed may also be a storage battery module formed by combining series connection and parallel connection of a plurality of cells. Moreover, the storage battery to be diagnosed may be a plurality of storage battery modules in which a plurality of single storage battery modules is connected in parallel.

Next, a configuration of the storage battery internal state estimation device 1 according to the first embodiment will be described with reference to FIGS. 1 and 2. FIG. 2 is a block diagram illustrating an example of a hardware configuration of the storage battery internal state estimation device 1 according to the first embodiment.

As illustrated in FIG. 1, the storage battery internal state estimation device 1 includes a data generation unit 5 and an estimation unit 60. The estimation unit 60 includes a separate estimation unit 6, an integrated estimation unit 7, and a deterioration diagnosis unit 8.

FIG. 2 illustrates an example of the hardware configuration of the storage battery internal state estimation device 1. In FIG. 2, the storage battery internal state estimation device 1 includes a controller 40. The controller 40 includes a processor 400 and a storage 401. The functions of the units included in the storage battery internal state estimation device 1, that is, the functions of the data generation unit 5, the separate estimation unit 6, the integrated estimation unit 7, and the deterioration diagnosis unit 8 are implemented by software, firmware, or a combination thereof. The software or firmware is described as programs and stored in the storage 401. The processor 400 reads the programs stored in the storage 401 and executes the programs to implement the functions of the units of the storage battery internal state estimation device 1.

The description refers back to FIG. 1. The current detection device 3 detects a current of the storage battery 2 and outputs time-series data of the current to the data generation unit 5. The voltage detection device 4 detects a voltage of the storage battery 2 and outputs time-series data of the voltage to the data generation unit 5. Here, the sampling period of the time-series data is assumed to be tₛ (seconds).

The present description assumes, unless otherwise specified, that the storage battery 2 to be diagnosed is a single storage battery cell, and the single storage battery cell is a single cell lithium ion battery. Note that in a case where the storage battery 2 is a plurality of storage batteries, the current detection device 3 and the voltage detection device 4 may detect the current and the voltage for each unit storage battery, respectively. In this case, each component described below performs the same operation as many times as the number of the storage batteries 2 to be diagnosed. Note, however, that the unit storage battery may be the storage battery cell or the storage battery module including a combination of series connection or parallel connection of the storage battery cells.

### <Data Generation Unit 5>

The data generation unit 5 calculates a series of data points of normalized capacity on the basis of an input current value “I” and the sampling period tₛ. Moreover, on the basis of an input voltage value “V” and the series of data points of the normalized capacity, the data generation unit 5 calculates a series of data points of N_{D} high-order differential voltages obtained by subjecting the voltage value “V” to j-th (j=1, 2,..., N_{D}) order differentiation with the normalized capacity. Also, on the basis of the input voltage value “V” and the series of data points of the normalized capacity, the data generation unit 5 calculates a series of data points of N_{I} high-order integral voltages obtained by subjecting the voltage value “V” to j-th (j=1, 2,..., N_{I}) order integration with the normalized capacity. Finally, the data generation unit 5 generates, as time-series data for estimation, the series of data points of each of the voltage value “V”, the normalized capacity, the N_{D} high-order differential voltages, and the N_{I} high-order integral voltages. The generated time-series data for estimation is input to the estimation unit 60.

The data generation unit 5 may store a part or all of the series of data points generated, and may output a part or all of a series of data points stored in the past together with the series of data points currently acquired or generated.

The series of data points generated by the data generation unit 5 can be expressed as the following expression (1).

$${\left\{\left({s}_{k} , {V}_{k}^{\left(j\right)}\right)\right\}}_{k = {k}_{0}}^{{k}_{f}} , j = - {N}_{I} , - {N}_{I} + 1 , … , {N}_{D} - 1 , {N}_{D} \qquad \text{[Expression 1]}$$

Note, however, that the series of data points expressed by the above expression (1) is defined as the following expression (2).

$${\left\{\left({x}_{k} , {y}_{k}\right)\right\}}_{k = {k}_{0}}^{{k}_{f}} : = \left\{\left({x}_{{k}_{0}} , {y}_{{k}_{0}}\right) , \left({x}_{{k}_{0 + 1}} , {y}_{{k}_{0} + 1}\right) , … , \left({x}_{{k}_{f}} , {y}_{{k}_{f}}\right)\right\} \qquad \text{[Expression 2]}$$

In the above expression (2), “k” is a discrete time, and when data acquisition for diagnosis is started at zero second with the sampling time of “t” seconds, a relationship of t=tₛ×k holds. In the expression, “sk” is the normalized capacity at the discrete time “k”, and “Vₖ^{(j)}” is a differential voltage, a voltage, or an integral voltage at the discrete time “k”. Moreover, “Vₖ^{(j)}” is defined as the following expression (3).

$${V}_{k}^{\left(j\right)} : = \left\{\begin{matrix}{\left(\frac{{d}^{j} V}{d {s}^{j}}\right|}_{s = {s}_{k}} & , & j = 1 , 2 , … , {N}_{D} \\ {V}_{k} & , & j = 0 \\ {\underbrace{{\int }_{{s}_{0}}^{{s}_{k}} ⋯ {\int }_{{s}_{0}}^{{s}_{k}} \text{}}}_{j} V {\underbrace{d s ⋯ d s}}_{j} & , & j = - {N}_{I} , … , - 1\end{matrix}\right) \qquad \text{(Expression 3]}$$

The normalized capacity sₖ can be calculated from capacity qₖ representing the storage capacity of electric charge (in coulombs) using the following expressions (4) and (5).

$${q}_{k + 1} = {q}_{k} + {t}_{s} {I}_{k} \qquad \text{(Expression 4]}$$

$${s}_{k} = \frac{{q}_{k}}{{q}_{t y p}} \qquad \text{[Expression 5)}$$

Here, “q_{typ},” in the denominator of the above expression (5) is standardized full charge capacity. Typically, the rated full charge capacity of the storage battery 2 to be diagnosed or the full charge capacity thereof when the storage battery 2 is new can be used as the standardized full charge capacity q_{typ}. Also, “Xₖ” means a value of “X” at the discrete time “k”. Moreover, the normalized capacity Sₖ is a state of charge (SOC) at the discrete time “k” that is a sampling parameter based on the standardized full charge capacity q_{typ}. When the normalized capacity sₖ is used, storage batteries having different rated full charge capacities and storage batteries having reduced full charge capacities due to individual differences or deterioration can be analyzed on the same basis. Note that the capacity qₖ may be used instead of the normalized capacity sₖ.

An initial electric charge q₀ of the storage battery 2 can be calculated by the following expressions (6) and (7) using a relationship between the SOC of the storage battery 2 and an open circuit voltage (OCV).

$$\text{SOC} = f \left(\text{OCV}\right) \qquad \text{[Expression 6]}$$

$${q}_{0} = {q}_{m a x} f \left({V}_{0}\right) \qquad \text{[Expression 7]}$$

Note that in the above expression (7), “qₘₐₓ” is the full charge capacity of the storage battery 2. As the full charge capacity qₘₐₓ, an estimated value of the full charge capacity of the storage battery 2 or the standardized full charge capacity qtyp, thereof can be used. Also, a function “f” can be obtained by, for example, interpolating a plurality of data points that represents the relationship between the SOC and the OCV with the horizontal axis representing the OCV and the vertical axis representing the SOC, the plurality of data points being obtained by repeating energizing and stopping the energization of a storage battery that is the same product as the storage battery 2 in advance. Alternatively, the initial electric charge q₀ may be calculated from “SOCe”, which is an estimated value of the SOC of the storage battery 2 estimated in a system equipped with the storage battery 2, by the following expression (8).

$${q}_{0} = {q}_{m a x} {\text{SOC}}_{\text{e}} \qquad \text{[Expression 8]}$$

The voltage value “V” and the normalized capacity sₖ are discrete series of data points. Therefore, the high-order differential voltage Vₖ^{(j)} (j=1,..., N_{D}) can be calculated using approximate differentiation by numerical differentiation based on Taylor expansion such as two-point approximation, three-point approximation, or five-point approximation of the voltage value “V” and the normalized capacity sₖ. In a case where a differential voltage is calculated using such approximate differentiation, there is a problem that noise included in the acquired current value “I” and voltage value “V” is amplified. In order to solve this problem, the acquired current value “I” and voltage value “V” may be subjected to noise rejection by a low-pass filter or noise rejection by Fourier analysis, wavelet analysis, or the like. As the low-pass filter, various types of filter processing are known such as a moving average filter, a Kolmogorov-Zurbenko filter, a Savitzky-Golay filter, an active filter, and a passive filter.

As a method of calculating the high-order integral voltage Vₖ^{(j)} (j=-N_{I},..., -1), a known trapezoidal rule, Simpson’s rule, or the like can be used. Constants of integration may be all zero in the simplest case.

The series of data points generated as described above, including the series of data points generated in the past, may be stored in the storage 401 inside the storage battery internal state estimation device 1 or on a data server, a cloud, or the like outside the storage battery internal state estimation device 1.

The estimation unit 60 estimates parameters of a model function of the storage battery 2 on the basis of the time-series data for estimation that is the series of data points acquired and generated by the data generation unit 5. The parameters of the model function may include a deterioration parameter serving as an index of a degree of deterioration of the storage battery 2. The estimation unit 60 typically includes the separate estimation unit 6, the integrated estimation unit 7, and the deterioration diagnosis unit 8 as illustrated in FIG. 1, but the configuration of the estimation unit 60 does not necessarily include all of the separate estimation unit 6, the integrated estimation unit 7, and the deterioration diagnosis unit 8.

### <Separate Estimation Unit 6>

The separate estimation unit 6 estimates parameters of a high-frequency function and a low-frequency function on the basis of the series of data points acquired and generated by the data generation unit 5. The high-frequency function is a function in which a relatively higher frequency component is dominant. The low-frequency function is a function in which a relatively lower frequency component is dominant.

Here, when f(x) represents a certain function, f^{(j)} (x) represents f(x), a high-order differential function of f(x), or a high-order integral function of f(x) depending on the value of “j”, and is defined as the following expression (9).

$${f}^{\left(j\right)} \left(x\right) : = \left\{\begin{matrix}\frac{{d}^{j} f \left(x\right)}{d {x}^{j}} & , & j ∈ \left\{1 , 2 , …\right\} \\ f \left(x\right) & , & j = 0 \\ {\underbrace{{\int }_{- ∞}^{x} ⋯ {\int }_{- ∞}^{x} \text{}}}_{j} f \left(x\right) {\underbrace{d x ⋯ d x}}_{j} & , & j ∈ \left\{- 1 , - 2 , …\right\}\end{matrix}\right) \qquad \text{[Expression 9]}$$

Hereinafter, a function serving as an element included in the high-frequency function is referred to as a “high-frequency element function”, and a function serving as an element included in the low-frequency function is referred to as a “low-frequency element function”. In addition, the high-frequency element function and the low-frequency element function are collectively referred to as “element functions”. The element function will be specifically described using a logistic function as an example. The logistic function is a kind of sigmoid function, and can be expressed by the following expression (10).

$$f \left(x ; k , μ , σ\right) = \frac{k}{1 + exp \left(- \frac{x - μ}{σ}\right)} \qquad \text{[Expression 10]}$$

In the above expression (10), “k” is a parameter representing a height, “µ” is a parameter representing a position, and “σ” is a parameter representing a scale. The scale in this case means the gentleness of the function. When the constant term is set to zero by finding an indefinite integral of the above expression (10), the function is expressed by the following expression (11).

$${f}^{\left(- 1\right)} \left(x ; k ; μ , σ\right) = k σ log \left(1 + exp \left(\frac{x - μ}{σ}\right)\right) \qquad \text{[Expression 11]}$$

The function expressed as the above expression (11) is called a softplus function.

Moreover, differentiating the above expression (10) gives the following expression (12).

$${f}^{\left(1\right)} \left(x ; k , μ , σ\right) = \frac{k exp \left(- \frac{x - μ}{σ}\right)}{σ {\left(1 + exp \left(- \frac{x - μ}{σ}\right)\right)}^{2}} \qquad \text{(Expression 12]}$$

The function expressed as the above expression (12) is called a peak function.

The sigmoid function and the function obtained by high-order differential/integral thereof can be expressed on the basis of distribution functions of various probability distributions such as a Gaussian distribution, a Cauchy distribution, a hyperbolic secant distribution, a Student’s t-distribution, and a Student’s z-distribution.

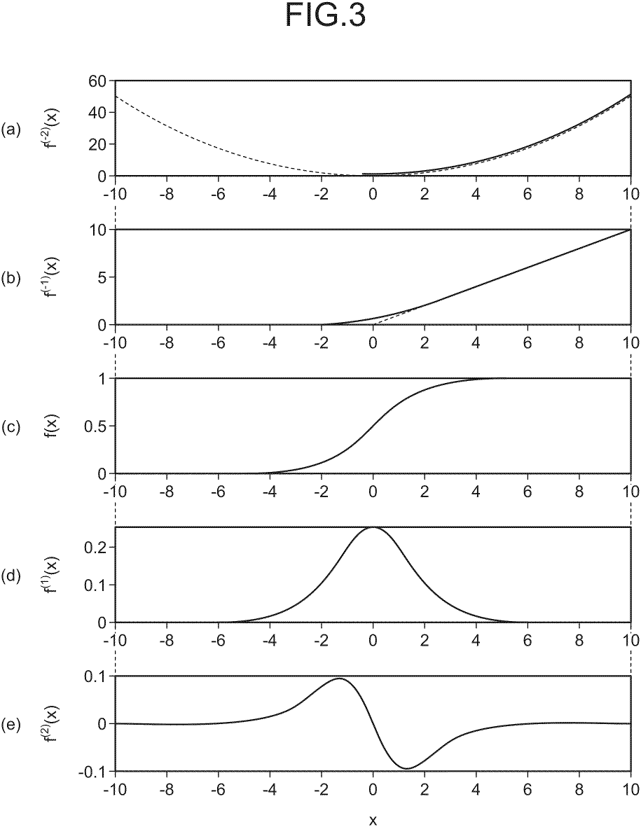

FIG. 3 is a set of graphs plotting curves from a second-order differential to a second-order integral of the logistic function used in a proposed technique of the first embodiment. When the horizontal axis is “x” and the vertical axis is “y”, FIG. 3 (a) illustrates y=f⁽⁻²⁾(x) which is a second-order integral function of the logistic function. Similarly, FIG. 3 (b) illustrates y-f⁽⁻¹⁾(x) which is a first-order integral function of the logistic function, and FIGS. 3 (c) illustrates y=f(x) which is the logistic function. Also, FIG. 3 (d) illustrates y=f⁽¹⁾(x) which is a first-order differential function of the logistic function, and FIG. 3 (e) illustrates y-f⁽²⁾(x) which is a second-order differential function of the logistic function. The set of functions from the second-order integral to the second-order differential can be expressed as y=f^{(j)}(x) (j=-2, -1, 0, 1, 2). Note that each waveform of FIG. 3 illustrates a case where values of the height “k”, the position µ, and the scale σ, which are the parameters in the logistic function f(x; k, µ, σ), are set to k=1, µ=0, and σ=1, respectively.

Note that a graph of y=x²/2 indicated by a broken line is superimposed on the second-order integral function y=f⁽⁻²⁾(x) in FIG. 3 (a). Also, a graph of y=x indicated by a broken line is superimposed on the first-order integral function Y=f⁽⁻¹⁾ (x) in FIG. 3 (b).

The original function y=f(x) is a sigmoid function and transitions smoothly from x=0 to x=1. The first-order differential function y-f⁽¹⁾(x) is a peak function and is represented by a bell-shaped curve around x=0. The second-order differential function y=f⁽²⁾ (x) has a shape in which peaks have the same height and opposite positive and negative signs. Meanwhile, the first-order integral function y=f⁽¹⁾ (x) is a softplus function, and is represented by a curve that asymptotically approaches zero as x→∞ when x<0 and asymptotically approaches y=x as x→∞ when x>1. This is apparent from the fact that the function asymptotically approaches log (1) when the second term of the above expression (11) is x<<0 and asymptotically approaches “x” when the second term of the above expression (11) is x>>0. Also, with the first-order integral function y=f⁽¹⁾(x) being the softplus function, the second-order integral function y=f⁽⁻²⁾(x) is obtained by further integrating the first-order integral function y-f⁽⁻¹⁾(x). Therefore, the second-order integral function y=f⁽⁻²⁾(x) is represented by a curve that asymptotically approaches zero as x→∞ when x<0, and asymptotically approaches a quadratic function y=x²/2+C with a constant “C” as x→∞ when x>1.

Here, the scale σ is the parameter representing the gentleness of the curve. Therefore, each curve becomes steeper when the value of the scale σ is decreased, or each curve becomes gentler when the scale σ is increased. In other words, a relative decrease in the scale σ results in a function in which the high-frequency component is dominant, that is, the high-frequency element function. Similarly, a relative increase in the scale σ results in a function in which the low-frequency component is dominant, that is, the low-frequency element function.

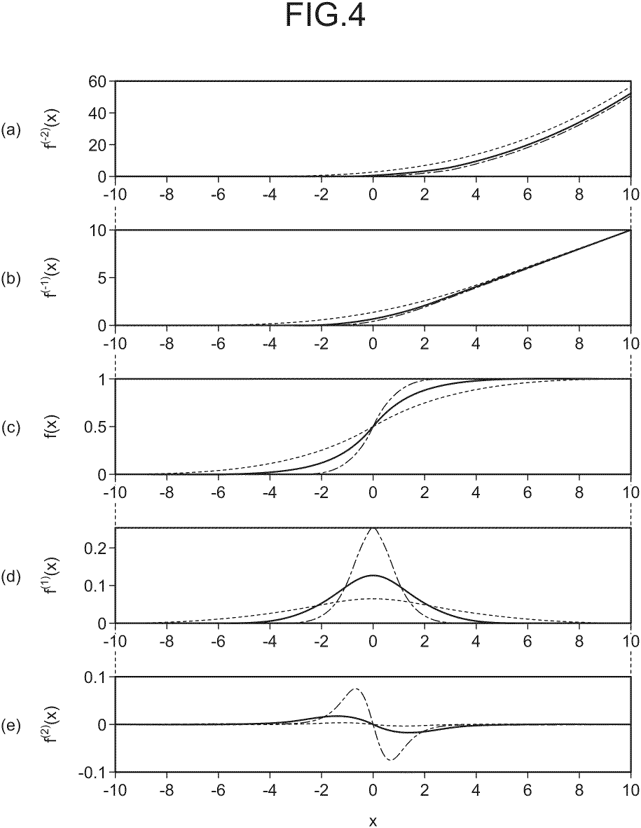

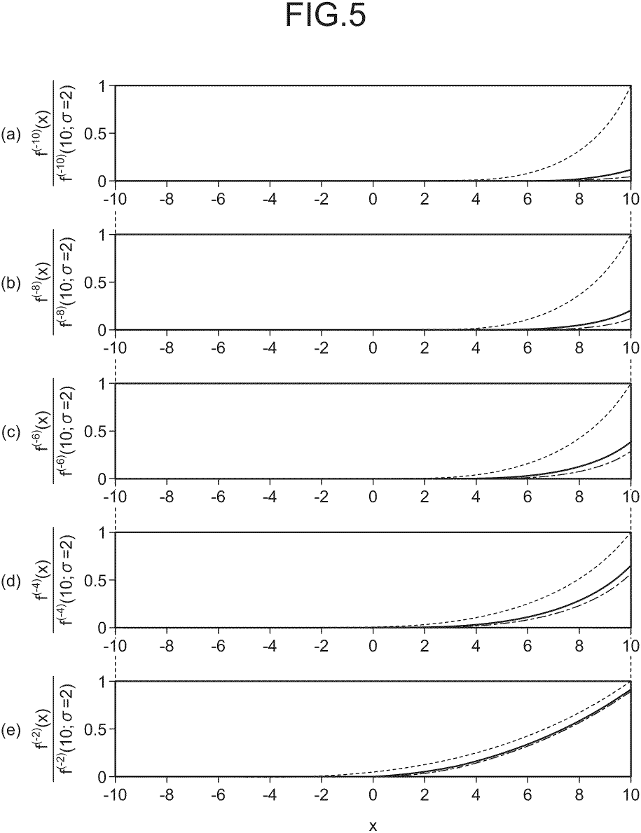

FIG. 4 is a set of graphs plotting curves from the second-order differential to the second-order integral when the value of the scale σ is changed in the logistic function used in the proposed technique of the first embodiment. Specifically, a solid line is a graph when σ=1, a broken line is a graph when σ=2, and an alternate long and short dash line is a graph when σ=0.5. As is apparent from each graph of FIG. 4, when the scale σ is increased, the curve becomes gentle. That is, an increase in the scale σ results in a lower-frequency global function. Conversely, when the scale σ is decreased, the curve becomes steep. That is, a decrease in the scale σ results in a higher-frequency local function.

FIG. 5 is a set of graphs plotting curves of even-order integral functions from a second-order integral to a tenth-order integral when the value of the scale σ is changed in the logistic function used in the proposed technique of the first embodiment. FIG. 5 (a) illustrates y-f⁽⁻¹⁰⁾(x) which is a tenth-order integral function of the logistic function. Similarly, FIG. 5 (b) illustrates y=f⁽⁻ ⁸⁾(x) which is an eighth-order integral function of the logistic function, and FIG. 5 (c) illustrates y=f⁽⁻⁶⁾(x) which is a sixth-order integral function of the logistic function. FIG. 5 (d) illustrates y-f⁽⁻⁴⁾(x) which is a fourth-order integral function of the logistic function, and FIG. 5 (e) illustrates y=f⁽⁻²⁾(x) which is a second-order integral function of the logistic function. These set of functions including the even-order integral functions can be expressed as y-f^{(j)}(x) (j=-10, -8, -6, -4, -2). Note that in each waveform of FIG. 5, a solid line is a graph when o=1, a broken line is a graph when o=2, and an alternate long and short dash line is a graph when σ=0.5. Also, for ease of understanding, all function values are divided by the value of f^{(j)}(x) (10; σ=2) and normalized such that f^{(j)}(x) (10; σ=2)=1 is obtained for the graph of the integral function of each order.

From the graphs of FIG. 5, it can be seen that as the order of integral gets higher, the function of o=2 which is the largest value of the scale σ becomes more dominant. Note that, as described above, the height “k” is the parameter determining the height of the sigmoid function, and the position µ is the parameter determining the peak position of the peak function.

The peak function may be a peak function with asymmetric skewness. As an example of the skew peak function, a density function of a skew normal distribution is known. Note, however, that the skew normal distribution includes an error function in the density function, and the distribution function includes an error function and an Owen’s T function. For this reason, these functions for which an analytical solution by an elementary function cannot be obtained are practically difficult to handle.

As another method, it is conceivable to use another peak function in which the peak positions match between the left and the right of the peak position, which however involves division into cases and thus is practically difficult to handle as well.

Thus, for the storage battery internal state estimation device 1 according to the present disclosure, a new skew sigmoid function is proposed. Although details will be described later, the storage battery internal state estimation device 1 according to the present disclosure uses a peak function as a model of a differential voltage curve of the storage battery 2. In the case where the peak function is used as the model of the differential voltage curve, it is desirable that the peak function and a sigmoid function obtained by integration of the peak function can be expressed by an elementary function such that the peak function can also be used as a model of a voltage curve. As a function satisfying this condition, the storage battery internal state estimation device 1 according to the present disclosure proposes a skew sigmoid function expressed by the following expression (13).

$${f}_{s k e w} \left(x ; k , μ , σ , v\right) = \frac{k}{1 - exp \left(- v\right)} \left(1 - exp \left(- v f \left(x ; k = 1 , μ , σ\right)\right)\right) \qquad \text{[Expression 13]}$$

When the skew sigmoid function is expressed by the above expression (13), the skew peak function obtained by differentiation of the skew sigmoid function can be expressed as the following expression (14).

$$\begin{matrix}{f}_{s k e w}^{\left(1\right)} \left(x ; k , μ , σ , v\right) = \\ \frac{k}{1 - exp \left(- v\right)} v {f}^{\left(1\right)} \left(x ; k = 1 , μ , σ\right) exp \left(- v f \left(x ; k = 1 , μ , σ\right)\right)\end{matrix} \qquad \text{[Expression 14]}$$

These new skew sigmoid function and skew peak function can adjust the degree of skew by adjusting a skew parameter v. Moreover, “f” is a known sigmoid function, and “f⁽⁻¹⁾” is a known peak function obtained by differentiation thereof. Thus, the above expression (14) enables conversion of various sigmoid functions and peak functions into skew sigmoid function and skew peak function.

In addition, the peak position of the skew peak function deviates from the peak position µ of the known peak function due to skewness. Thus, the peak position of the skew peak function is derived. When “xₘ” represents the peak position of the skew peak function, the differentiation by “x” is zero at the peak position xₘ so that the solution is obtained by solving the following expression (15).

$${f}_{s k e w}^{\left(1\right)} \left({x}_{m}\right) = 0 ↔ {f}^{\left(1\right)} \left({x}_{m}\right) - v f {\left({x}_{m}\right)}^{2} = 0 \qquad \text{[Expression 15]}$$

For example, in a case where a logistic function is used as the known peak function, the peak position xₘ expressed by the following expression (16) is obtained.

$${x}_{m} = μ - σ ln \left(\frac{- p + \sqrt{{p}^{2} + 4}}{2}\right) \qquad \text{[Expression 16]}$$

Similarly, in a case where another function is used, an expression of the peak position represented by an elementary function is obtained in many examples. For example, in a case where a peak function of a hyperbolic secant distribution expressed by the following expression (17) is used, the peak position xₘ expressed by the following expression (18) is obtained.

$${f}^{\left(1\right)} \left(x\right) = \frac{k}{2 σ} sech \left(\frac{π}{2} ⋅ \frac{x - μ}{σ}\right) \qquad \text{[Expression 17]}$$

$${x}_{m} = μ + σ ⋅ \frac{2}{π} ln \left(- \frac{p}{π} + \sqrt{{\left(\frac{p}{π}\right)}^{2} + 1}\right) \qquad \text{[Expression 18]}$$

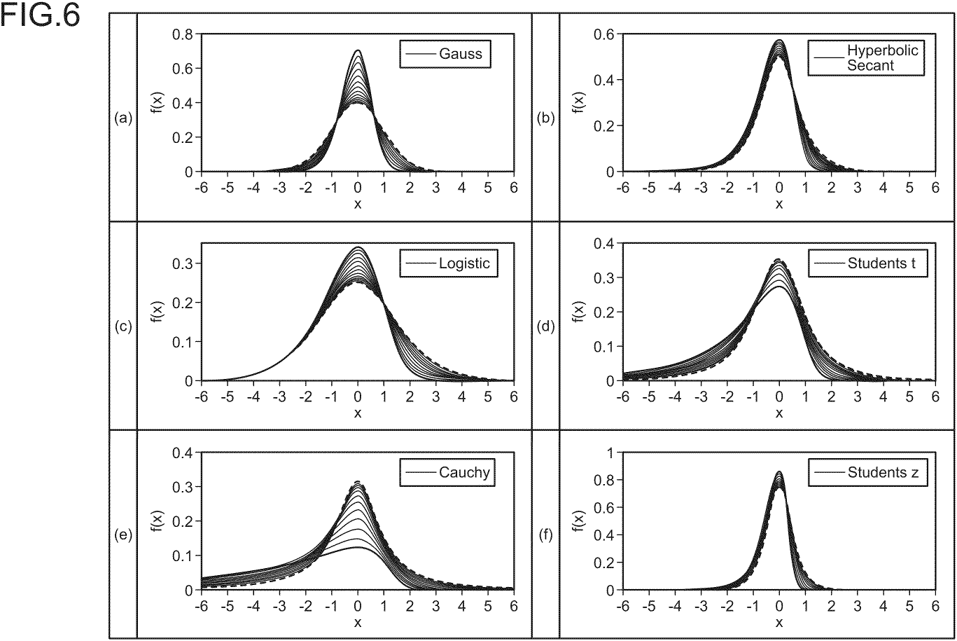

FIG. 6 is a set of graphs plotting curves for each skew parameter v when the value of the skew parameter v is gradually varied for a skew peak function generated using density functions of six different types of distributions by the proposed technique of the first embodiment. Specifically, FIG. 6 (a) is an example of the Gaussian distribution, FIG. 6 (b) is an example of the hyperbolic secant distribution, and FIG. 6 (c) is an example of the logistic distribution. FIG. 6 (d) is an example of the Student’s t-distribution, FIG. 6 (e)is an example of the Cauchy distribution, and FIG. 6 (f)is an example of the Student’s z-distribution. In each example, the skew peak function is constructed using the density function of the corresponding distribution as “f” in the above expression (14), and a change in the shape of the curve when the skew parameter v is gradually increased is plotted. A broken line in each graph indicates a curve when v=0.

Referring to the graphs of FIG. 6, an asymmetric peak function is generated in each graph. It can also be seen that, on each graph, the degree of skew is successfully adjusted by the skew parameter. Therefore, the above expression (14) can be used to generate the asymmetric peak function.

Although there are other techniques for constructing the skew peak function, the technique using the above expressions (13) and (14) have the following advantages.

(i) The skew peak function can be constructed from various known sigmoid functions and peak functions, and thus the technique has high versatility.

(ii) The skewness can be expressed only by adding one skew parameter v, and thus the technique is useful in parameter estimation described later.

(iii) If the known sigmoid function to be used can be expressed by an elementary function, the skew sigmoid function and the skew peak function can also be expressed by an elementary function and are practically easy to handle, whereby the technique is particularly useful for modeling the voltage curve and the differential voltage curve of the storage battery.

(iv) The analytical solution of the peak position of the skew function is obtained by an elementary function in many cases, and thus the technique is practically useful particularly for determining an initial value in parameter estimation described later.

Hereinafter, from the viewpoint of simplification of description and ease of understanding, description will be made using a normal peak function unless otherwise specified. Note that, it goes without saying that a similar discussion can be made by using a known peak function or the skew peak function of the above expression (14) instead of the normal peak function.

Next, a relationship between the element function and the voltage curve of the storage battery 2 will be described. First, the voltage value “V” when the storage battery 2 is charged and discharged at a constant current is expressed by the following expression (19).

$$V = {U}_{p} - {U}_{n} + R I \qquad \text{[Expression 19]}$$

In the above expression (19), “Uₚ” is a positive electrode potential, “Un” is a negative electrode potential, “I” is a current flowing through the storage battery 2, and “R” is a resistance of the storage battery 2.

Next, an electrode potential curve is considered. In a general storage battery, a relationship between ion concentration and an electrode potential is described by the Nernst equation. However, an actual potential curve includes a flat region due to a two-layer coexistence region, a stepwise change due to a phase change, a nearly linear change due to insertion of ions into a single phase, and the like.

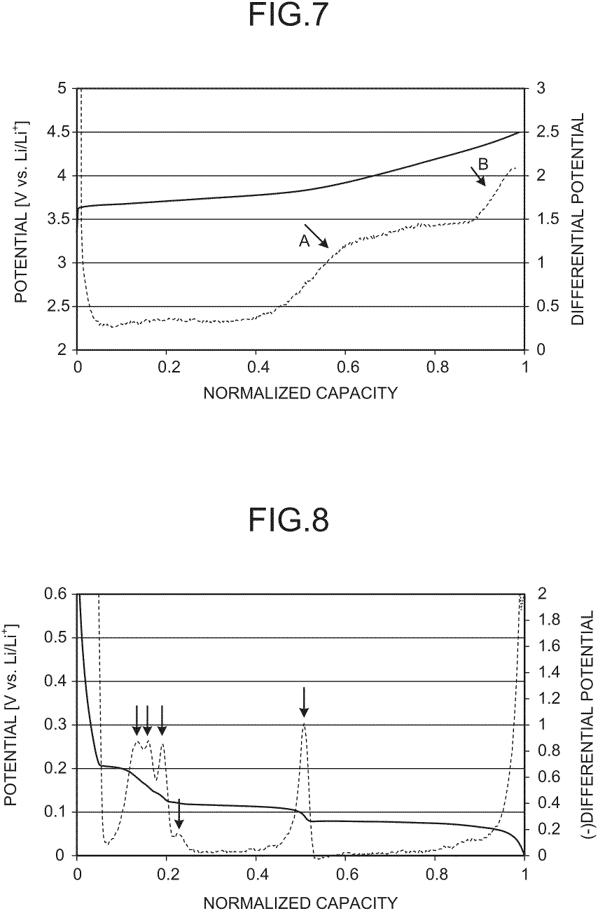

FIG. 7 is a characteristic chart illustrating an example of a potential curve of a positive electrode and a differential potential curve of the positive electrode in a general lithium ion battery including an NMC-based positive electrode and a graphite negative electrode. In FIG. 7, the horizontal axis represents the normalized capacity of the positive electrode, the left vertical axis represents the potential, and the right vertical axis represents the differential potential. A solid line represents the potential curve, and a broken line represents the differential potential curve. Note, however, that since the normalized capacity equal to zero for the storage battery cell is usually regulated by the negative electrode potential, on this characteristic chart, a region near the normalized capacity equal to zero of the positive electrode is not used. As can be seen from FIG. 7, for many materials including NMC, the potential curve of the positive electrode has a shape in which the potential changes gently.

Here, when “sₚ” represents the normalized capacity of the positive electrode, a positive electrode potential function fₚ(sₚ) can be expressed by the following expression (20), for example. _{[}

$$\begin{matrix}{f}_{p} \left({s}_{p}\right) = \\ {c}_{p} + {b}_{p} {s}_{p} + {\sum }_{i = 1}^{{n}_{p}} f \left({s}_{p} ; {k}_{p i} , {μ}_{p i} , {σ}_{p i}\right) + {\sum }_{i = {n}_{p} + 1}^{{n}_{p} + {m}_{p}} {f}^{\left(- 1\right)} \left({s}_{p} ; {k}_{p i} , {μ}_{p i} , {σ}_{p i}\right)\end{matrix} \qquad \text{[Expression 20]}$$

Moreover, differentiating the above expression (20) gives a positive electrode differential potential function fₚ⁽¹⁾(sₚ) expressed by the following expression (21).

$$\begin{matrix}{f}_{p}^{\left(1\right)} \left({s}_{p}\right) = \\ {b}_{p} + {\sum }_{i = 1}^{{n}_{p}} {f}^{\left(1\right)} \left({s}_{p} ; {k}_{p i} , {μ}_{p i} , {σ}_{p i}\right) + {\sum }_{i = {n}_{p} + 1}^{{n}_{p} + {m}_{p}} f \left({s}_{p} ; {k}_{p i} , {μ}_{p i} , {σ}_{p i}\right)\end{matrix} \qquad \text{[Expression 21]}$$

As in the above expression (21), the positive electrode differential potential function fₚ⁽¹⁾ (sₚ) is expressed by a sum of a constant term, nₚ peak functions, and mₚ sigmoid functions as the element functions. Therefore, the positive electrode potential function fₚ(sₚ) expressed by the above expression (20) obtained by integrating expression (21) is expressed by a sum of a constant term, a linear term, nₚ sigmoid functions, and mₚ softplus functions as the element functions.

Using the sigmoid function and the peak function as described above can satisfactorily express the local change of the potential curve or the differential potential curve. Note that expressions of the above expressions (20) and (21) are merely examples, and other element functions may be used instead of these element functions. Moreover, it is not always necessary to use the function including the parameters expressing the height “k”, the position µ, and the scale σ as the element function. Note that the differential voltage curve in FIG. 7 can be expressed by a constant term and two sigmoid functions corresponding to points indicated by arrows A and B.

FIG. 8 is a characteristic chart illustrating an example of a potential curve of the negative electrode and a differential potential curve of the negative electrode in the same lithium ion battery as that illustrated in FIG. 7. In FIG. 8, the horizontal axis represents the normalized capacity of the negative electrode, the left vertical axis represents the potential, and the right vertical axis represents the differential potential whose sign is inverted. A solid line represents the potential curve, and a broken line represents the differential potential curve. Note, however, that since the normalized capacity equal to one for the storage battery cell is usually regulated by the positive electrode potential, on this characteristic chart, a region near the normalized capacity equal to one of the negative electrode is not used.

The potential curve of the negative electrode that is graphite is different from the potential curve of the positive electrode that is NMC, and FIG. 8 illustrates a sigmoid-like potential change due to a phase change in some places while having a smooth curve due to a two-layer coexistence region. This change corresponds to peak-like curves at positions indicated by arrows in the differential potential curve.

Here, when “sₙ” represents the normalized capacity of the negative electrode, a negative electrode potential function fₙ(sₙ) can be expressed by the following expression (22), for example.

$${f}_{n} \left({s}_{n}\right) = {c}_{n} + {\sum }_{i = 1}^{{m}_{n}} \left(1 - f \left({s}_{n} ; {k}_{n i} {μ}_{n i} , {σ}_{n i}\right)\right) \qquad \text{[Expression 22]}$$

Moreover, differentiating the above expression (22) gives a negative electrode differential potential function fₙ⁽¹⁾(sₙ) expressed by the following expression (23).

$${f}_{n}^{\left(1\right)} \left({s}_{n}\right) = - {\sum }_{i = 1}^{{m}_{n}} {f}^{\left(1\right)} \left({s}_{n} ; {k}_{n i} , {μ}_{n i} , {σ}_{n i}\right) \qquad \text{[Expression 23]}$$

As in the above expression (23), the negative electrode differential potential function fₙ⁽¹⁾ (sₙ) is expressed by a sum of mₙ peak functions as the element functions. Therefore, the negative electrode potential function fₙ(sₙ) expressed by the above expression (22) obtained by integrating expression (23) is expressed by a sum of a constant term and mₙ sigmoid functions as the element functions.

The differential potential curve of FIG. 8 enables accurate modeling by making a peak function correspond to the position indicated by the arrow. Note that, as with the example of the positive electrode, the element function used here is an example, and another element function may be used. Moreover, the rise of the differential voltage at a left end may be modeled by a peak function, or another function may be used as the element function. For example, a sigmoid function may be used. Alternatively, an exponential function as expressed by the following expression (24) may be used.

$$f \left(x ; μ , σ\right) = exp \left(- \frac{x - μ}{σ}\right) \qquad \text{[Expression 24]}$$

A voltage function of the storage battery cell can be expressed by the following expression (25) in accordance with the above expression (19) and using the above expressions (20) and (22).

$$\begin{matrix}{f}_{b} \left(s\right) = {f}_{p} \left(s\right) - {f}_{n} \left(s\right) + R I \\ = {\sum }_{i = 1}^{{n}_{e}} {f}_{e , i} \left(s ; {θ}_{i}\right)\end{matrix} \qquad \text{[Expression 25]}$$

In the above expression (25), an argument of each function is the normalized capacity “s” of the storage battery cell. Also, “f_{e,i}” is an i-th element function, and “θᵢ” is a vector of parameters included in the i-th element function f_{e,i}. For example, θᵢ=bₚ when f_{e,i}(s)=bₚs, and θᵢ₌ [k_{ni,µ} µₙᵢ, σ_{ni]} ^{T} when f_{e,i}(s) =f (Sₙ; kₙᵢ, µₙᵢ, σₙᵢ) .

As described above, the model functions of the storage battery cell voltage and the storage battery cell differential voltage can be expressed by the sum of the element functions including at least one of the softplus function, the sigmoid function, and the peak function described above.

### <Separate Estimation Unit 6>

The separate estimation unit 6 estimates the parameters of the high-frequency function and the low-frequency function on the basis of the series of data points acquired and generated by the data generation unit 5. The specifics are as follows.

The positive electrode voltage curve and the positive electrode differential voltage curve are expressed by the sum of the element functions as expressed by the above expressions (20) and (21). It is thus not advisable to collectively estimate the parameters of all the functions. Therefore, the first embodiment amplifies at least one specific element function and attenuates the other element functions, thereby replacing the other element functions with zero or an approximate function and estimating the parameters of the approximate function and the specific element function. This technique utilizes a property that by high-order differential, the element function of a higher frequency is extracted because the element function of a lower frequency is further attenuated, and a property that by high-order integral, the element function of a lower frequency is extracted because the element function of a higher frequency is further attenuated.

More specific description is as follows. In the already defined function f^{(j)}(x;k,µ,σ), when z=(x-µ)/σ and constants of integration are all zero, a relationship expressed by the following expression (26) is established for an arbitrary integer “j”.

$${f}^{\left(j\right)} \left(x ; k , μ , σ\right) = {σ}^{- j} {f}^{\left(j\right)} \left(z ; k\right) \qquad \text{[Expression 26]}$$

In the above expression (26), focusing attention on the point that a function f^{(j)}(z;k) with “z” as an argument on the right side is a differential/integral with respect to “z” instead of “x”, when σ₁<σ₂, a relationship expressed by the following expression (27) is established.

$$\begin{matrix}{f}^{\left(j\right)} \left(x ; {k}_{1} , {μ}_{1} , {σ}_{1}\right) = \\ {σ}_{1}^{- j} {f}^{\left(j\right)} \left(z ; k\right) > {σ}_{2}^{- j} {f}^{\left(j\right)} \left(z ; k\right) = {f}^{\left(j\right)} \left(x ; k , μ , {σ}_{2}\right)\end{matrix} \qquad \text{[Expression 27]}$$

When σ₁>σ₂, a relationship expressed by the following expression (28) is established.

$$\begin{matrix}{f}^{\left(j\right)} \left(x ; {k}_{1} , {μ}_{1} , {σ}_{1}\right) = \\ {σ}_{1}^{- j} {f}^{\left(j\right)} \left(z ; k\right) < {σ}_{2}^{- j} {f}^{\left(j\right)} \left(z ; k\right) = {f}^{\left(j\right)} \left(x ; k , μ , {σ}_{2}\right)\end{matrix} \qquad \text{[Expression 28]}$$

In the above expressions (27) and (28), the larger an absolute value of “j” is, the larger a difference in magnitude relationship between the left side and the right side is. That is, as long as there is a magnitude relationship between σ₁ and σ₂, it is possible to relatively attenuate one and relatively amplify the other by setting “j” to be arbitrarily large.

Note that in expressions (27) and (28), functions obtained by differentiating/integrating the same function by the same order are compared with each other, but the present disclosure is not limited thereto. Even functions obtained by differentiating/integrating different functions by different orders can relatively attenuate one and relatively amplify the other depending on the magnitude relationship between σ₁ and σ₂. Note, however, that when two functions are differentiated or integrated repeatedly, which function is relatively amplified or attenuated depends not only on the magnitude relationship between σ₁ and σ₂ but also on the shapes of the two functions.

When data of a specific high-frequency or low-frequency region is extracted by high-order differential/integral, parameters of a corresponding element function are estimated such that an error with the extracted data is reduced. At that time, parameters of an element function corresponding to the attenuated component outside the extracted region may be simultaneously estimated using an approximate function. For example, approximation may be performed with a constant, or approximation with an n-th order function as described with reference to FIG. 3 may be used. That is, the form of the approximate function is not limited.

A final objective is to accurately model the voltage curve of the storage battery cell while separating the positive electrode potential curve and the negative electrode potential curve by the voltage function. Therefore, an evaluation function is used to minimize the evaluation function. When θᵢ:=[θ^{T}₁,θ^{T}₂,...,θ^{T}ₙₑ]^{T} and “wⱼ” is a weighting factor, an evaluation function J₀ to be minimized can be expressed as the following expression (29).

$${J}_{0} \left(θ\right) = {\sum }_{j = - {N}_{I}}^{{N}_{D}} {\sum }_{k = {k}_{0}}^{{k}_{f}} {w}_{j} {\left({f}_{b}^{\left(j\right)} \left({s}_{k} ; θ\right) - {V}_{k}^{\left(j\right)}\right)}^{2} \qquad \text{[Expression 29]}$$

As in the above expression (29), when a difference between the voltage function and the high-order differential/integral of each voltage data is included in the evaluation function, an SN ratio can be improved. Note that an initial time and an end time of the data to be used may be set to different values for different values of “j”. Also, here, although a sum of square errors is used for simplicity, the present disclosure is not limited thereto. The evaluation function can be described in various methods.

Moreover, when a ρ (q)-th element function is extracted by q-th order differential/integral, an evaluation function J₁ to be minimized as expressed by the following expression (30) can be used.

$${J}_{1} \left({θ}_{ρ \left(q\right)} , {δ}_{q}\right) = {\sum }_{k = {k}_{0}}^{{k}_{f}} {\left({f}_{e , ρ \left(q\right)}^{\left(q\right)} \left({s}_{k} ; {θ}_{ρ \left(q\right)}\right) + {g}_{q} \left({s}_{k} ; {δ}_{q}\right) - {V}_{k}^{\left(q\right)}\right)}^{2} \qquad \text{[Expression 30]}$$

In the above expression (30), “p (q)” represents an index of the element function extracted by q-th order differential/integral. Furthermore, “g_{q}” is an approximate function of an attenuated element function when q-th order differential/integral is performed, and “δq” is a vector in which parameters of the approximate function are lined up. Note that the approximate function is not essential and may be zero.

When the minimization evaluation by the above expression (30) is repeated, a first evaluation function is expressed by the following expression (31).

$$\begin{matrix}{J}_{l} \left({θ}_{ρ \left(q l\right)} , {δ}_{q l}\right) = \\ {\sum }_{k = {k}_{0}}^{{k}_{f}} {\left({f}_{e , ρ \left(q l\right)}^{\left(q l\right)} \left({s}_{k} ; {θ}_{ρ \left(q l\right)}\right) + {g}_{q l} \left({s}_{k} ; {δ}_{q l}\right) - {h}_{l} \left({s}_{k}\right) - {V}_{k}^{\left(q l\right)}\right)}^{2}\end{matrix} \qquad \text{[Expression 31]}$$

In the above expression (31), “qₗ” represents the order of differential/integral used in the first evaluation function. Moreover, “hₗ” is a function based on results of estimation up to (l-1)-th round, and can be expressed by the following expression (32), for example.

$${h}_{l} \left({s}_{k}\right) = {\sum }_{i = 1}^{l - 1} {f}_{e , ρ \left({q}_{i}\right)}^{\left({q}_{i}\right)} \left({s}_{k} ; {θ}_{ρ \left({q}_{i}\right)}^{∗}\right) \qquad \text{(Expression 32]}$$

In the above expression (32), “θ*_{p(qi)}” represents an estimated value of “θ_{p(qi)}” calculated so as to minimize an evaluation function Jᵢ. The function hₗ allows for the use of the functions estimated in the past, whereby the current estimation calculation can be made more accurate and stabilized. In addition, typically, an operation of creating and minimizing the evaluation function in order from differential data or integral data of a higher order is repeated. For high-order differential, a higher high-frequency function is often more dominant in the differential data of a lower order. Therefore, processing of extracting and estimating the higher high-frequency function by higher-order differential is performed. This makes it possible to remove the influence of the higher high-frequency function by subtracting it in the estimation of a lower high-frequency function in the differential data of a lower order.

Similarly, for high-order integral, a lower low-frequency function is often more dominant in the integral data of a lower order. Therefore, processing of extracting and estimating the lower low-frequency function by higher-order integral is performed. This makes it possible to remove the influence of the lower low-frequency function by subtracting it in the estimation of a higher low-frequency function in the integral data of a lower order.

As a technique of estimating the parameters by minimizing the evaluation function of the above expressions (29) to (31), a known nonlinear optimization technique can be used. For example, a Gauss-Newton method, a Levenberg-Marquardt algorithm, or the like can be used as the optimization technique. Note that there may be some information regarding the parameters to be estimated such as information indicating that a certain parameter is non-negative. In that case, by including these pieces of information as constraints, the optimization technique may be formulated as a nonlinear optimization problem with constraints. As the optimization technique in this case, a penalty function method, a sequential quadratic programming method, a generalized reduced gradient (GRG) method, or the like can be used.

Note that the optimization techniques without constraints and with constraints described herein are examples, and an optimization technique such as a metaheuristic may be used as another optimization technique. In addition, the optimization technique may be selectively used according to the scale of the problem such as the number of parameters and the scale of the calculation resources such as the processing speed and the memory amount.

In the above expressions (29) to (31), the evaluation function is constructed by the sum of square errors, but the method of constructing the evaluation function is not limited thereto. For example, instead of the sum of square errors, the evaluation function may be constructed by a sum of n-th power errors by “n” which is n≠2. Alternatively, the evaluation function may be constructed by a weighted sum including a regularization term or the like.

### <Integrated Estimation Unit 7>

On the basis of the parameters estimated by the separate estimation unit 6, the integrated estimation unit 7 estimates the parameters again so as to minimize the above expression (23). Specifically, all the parameters are estimated again by including at least any of the parameters separately obtained by the separate estimation unit 6 and the parameters not obtained by the separate estimation unit 6, and using the parameters already estimated as initial values of the estimation here.

The separate estimation unit 6 repeats the estimation of only some of the element functions. In this repetitive processing, the parameter is estimated by setting the other element function attenuated by the high-order differential/integral to zero or replacing it with the approximate function. As a result, the estimated parameter possibly includes an error due to the influence of such approximation processing. Thus, the integrated estimation unit 7 performs processing of collecting the estimated parameters and integrating all the parameters and all the element functions to estimate the parameters of the storage battery voltage function again. In this estimation processing, the parameters already estimated by the separate estimation unit 6 are set as the initial values, which increases the probability that a result of estimation by the integrated estimation unit 7 converges to a value close to an optimal value. Therefore, the processing in the integrated estimation unit 7 can obtain the result of estimation with a small error due to the estimation/approximation.

As described above, the voltage function of the storage battery 2 can be accurately obtained. Moreover, even when there is a difference in shape between the positive electrode potential curve and the negative electrode potential curve, the respective functions can be estimated separately while separating the curves using the high-order differential/integral.

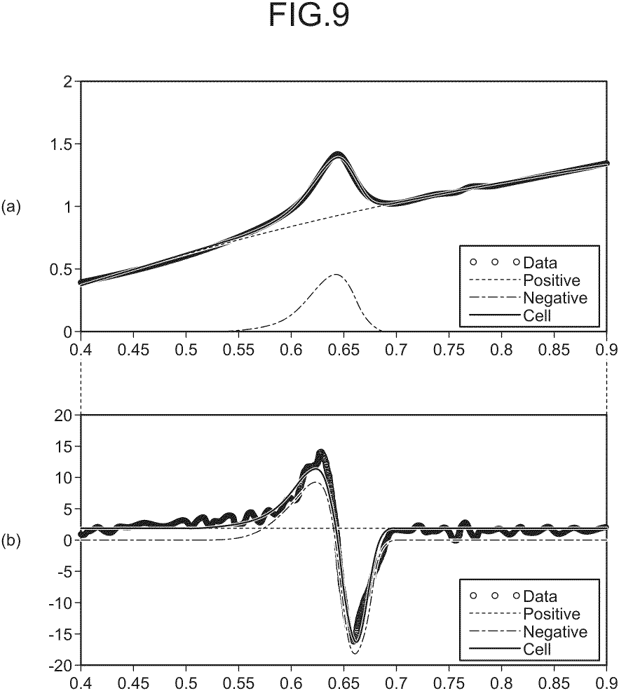

FIG. 9 is a set of graphs illustrating an example of separation and estimation by high-order differential performed using the proposed technique of the first embodiment. FIG. 9 (a)illustrates partial data of a first-order differential voltage of the storage battery voltage and a result of estimation therefor. FIG. 9 (b) illustrates partial data of a second-order differential voltage of the storage battery voltage and a result of estimation therefor. In both of the graphs, a broken line represents a result of estimation of the function of the positive electrode, an alternate long and short dash line represents a result of estimation of the function of the negative electrode, and a solid line represents a result of estimation of the function of the storage battery cell. Note that the partial data is represented by white circles but appears almost as a thick line in both of the graphs due to the plot interval being narrow. In the processing illustrated in FIG. 9, first, some function parameters are estimated using the partial data of the second-order differential. Then, the remaining function parameters are estimated on the basis of the result of estimation and the partial data of the first-order differential. A more specific processing procedure will be described below.

For the second-order differential data, processing of minimizing the above expression (30) is performed. First, the function expressed by the above expression (30) is set as the following expression (33) for q=2.

$$\begin{matrix}{f}_{e , ρ \left(q\right)}^{\left(q\right)} \left({s}_{k} ; {θ}_{ρ \left(q\right)}\right) = {f}_{s k e w}^{\left(q\right)} \left({s}_{k} ; {k}_{1} , {μ}_{1} , {σ}_{1} , v\right) \\ {g}_{q} \left({s}_{k} ; {δ}_{q}\right) = d\end{matrix} \qquad \text{[Expression 33]}$$

In the above expression (33), θp(q)=[k,µ,σ,ν] and δ_{q}=d.In expression (33), a low-frequency component derived from the positive electrode voltage curve is sufficiently attenuated in the second-order differential. Therefore, the constant term “d” is approximately expressed as an approximate function. Meanwhile, in high-order differential, a high-frequency component is emphasized so that modeling with high accuracy is important. Therefore, with the high-frequency function as a skew sigmoid function, a second-order differential thereof is used. FIG. 9 specifically corresponds to the storage battery using graphite for the negative electrode. In the case of this storage battery, a peak of a differential potential at intermediate capacity of graphite has an asymmetric shape as in FIG. 8. Therefore, expression using the skew parameter is important.

As described above, the estimation processing is performed only on the second-order differential voltage data. Accordingly, a smaller number of parameters are estimated first, which makes the estimation less difficult. As a result, the parameters can be estimated more accurately and stably.

Note that the estimation processing here uses the second-order differential voltage, but may use higher-order differential voltage data. In that case, if the low-frequency component derived from the positive electrode potential function can be approximated by a constant for the second-order differential data, the low-frequency component may be approximated as zero for data subjected to third-order or higher differentiation. However, in general, the higher the order of differentiation, the more the noise is amplified, so that finer preprocessing by filtering or the like is required. Therefore, it is desirable to determine the order of differentiation in consideration of a trade-off between an effect of attenuating a lower frequency component and an effect of amplifying the noise.

Next, on the basis of the parameters estimated for the second-order differential data, the voltage function of the storage battery cell is used to estimate “θ” that minimizes “J₀” in the above expression (29).

Here, a function expressed by the following expression (34) is used as the voltage function of the storage battery cell.

$${f}_{b} \left(s ; θ\right) = f \left(s ; {k}_{2} , {μ}_{2} , {σ}_{2}\right) + {f}_{s k e w} \left(s ; {k}_{1} , {μ}_{1} {σ}_{1} , v\right) \qquad \text{[Expression 34]}$$

Then, the above expression (34) is used to estimate “θ” with θ_{p(q)}=θ*_{p(q)}as an initial value of a parameter of a function f_{skew}. The parameter “d” of the approximate function “g_{q}” may also be used. For example, when the function “f” in expression (34) is a sigmoid function of a logistic distribution, it is assumed that “d” approximates a slope at an inflection point of the sigmoid. Then, when the value of f⁽¹⁾ at the point of s=µ that is the inflection point is compared with an estimated value d* of “d”, the following expression (35) is derived.

$${f}^{\left(1\right)} \left(s = {μ}_{2} ; {k}_{2} , {μ}_{2} , {σ}_{2}\right) = {\left(\frac{{k}_{2} exp \left(- \frac{s - {μ}_{2}}{{σ}_{2}}\right)}{{σ}_{2} {\left(1 + exp \left(- \frac{s - {μ}_{2}}{{σ}_{2}}\right)\right)}^{2}}\right|}_{s = {μ}_{2}} = \frac{{k}_{2}}{4 {σ}_{2}} \approx {d}^{∗} \qquad \text{[Expression 35]}$$

As expressed in the above expression (35), an initial value of the estimation of k₂ can be set to 4σ₂d*

As described above, the result of estimation for the second-order differential voltage data is used as the initial value in the estimation of the parameter that minimizes the evaluation function of the above expression (29), whereby the parameter estimation can be started from a point close to a global optimal solution of the above expression (29). This processing increases the probability that all the parameters converge to the global optimal solution or a point close thereto. In addition, the above expression (29) uses not only the differential voltage data but also the second-order differential voltage data, whereby the SN ratio for the high-frequency component can be improved.

Note that the processing here uses only the differential voltage data and the second-order differential voltage data for the sake of simplicity, but may use voltage data or high-order integral voltage data other than the second-order differential voltage data. For example, it is sufficient to use the high-order integral data for extracting the low-frequency component.

### <Deterioration Diagnosis Unit 8>

The deterioration diagnosis unit 8 compares data of two or more of the storage batteries 2 having different degrees of deterioration to estimate a deterioration parameter of the storage batteries 2. The deterioration parameter may be estimated using both data used for past estimation and data used for current estimation. Alternatively, in the current estimation processing, when the current detection device 3 and the voltage detection device 4 detect current data and voltage data of two or more of the storage batteries 2, respectively, a relative degree of deterioration may be estimated by comparing the respective pieces of data. In this case, the data generation unit 5, the separate estimation unit 6, and the integrated estimation unit 7 also apply the contents described so far to a plurality of pieces of the storage battery data.

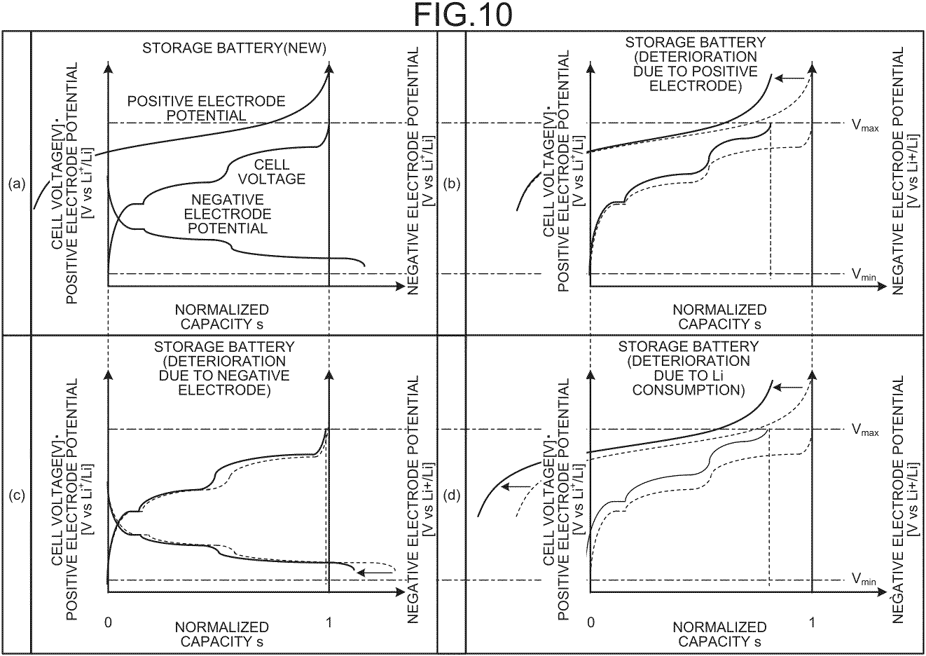

FIG. 10 is a set of graphs for explaining deterioration modes reflected in the voltage function of the storage battery cell used in the description of the proposed technique of the first embodiment. FIG. 10 illustrates a relationship among a cell voltage, which is a voltage of the storage battery cell, a positive electrode potential, and a negative electrode potential. The storage battery cell is a lithium ion battery. FIG. 10 (a) is an example of a case where the storage battery cell is new, and FIG. 10 (b) is an example of a case where the positive electrode of the storage battery cell is deteriorated. FIG. 10 (c)is an example of a case where the negative electrode of the storage battery cell is deteriorated, and FIG. 10 (d) is an example of a case where deterioration occurs due to lithium consumption.

As can be seen from the characteristic in FIG. 10 (a), the lower limit of the cell voltage is substantially defined as the negative electrode potential with the positive electrode still having a margin for charging, whereas the upper limit of the cell voltage is substantially defined as the positive electrode potential with the negative electrode still having a margin for charging.

When the positive electrode is deteriorated, as in FIG. 10 (b), the positive electrode potential curve is reduced to the left due to a decrease in the positive electrode capacity, and the cell voltage curve is also affected thereby. Likewise, when the negative electrode is deteriorated, as in FIG. 10 (c), the negative electrode potential curve is reduced to the left due to a decrease in the negative electrode capacity, and the cell voltage curve is also affected thereby. Note that the positive electrode capacity is the full charge capacity of the positive electrode, and the negative electrode capacity is the full charge capacity of the negative electrode.

When deterioration occurs due to lithium consumption, as in FIG. 10 (d), the positive electrode potential curve is shifted relatively to the left, and the cell voltage curve is also affected thereby. The reason why the positive electrode potential curve is shifted relatively to the left is considered that lithium ions released from the negative electrode during charging are not all transferred to the positive electrode, and are consumed by side reactions such as growth of a negative electrode solid-electrolyte interface (SEI) and precipitation of lithium.

In addition to the above, there is also a deterioration mode in which the resistance of the storage battery cell increases. Strictly speaking, various factors such as contact resistance, electrolytic solution resistance, reaction resistance in each of the positive electrode and the negative electrode, and diffusion resistance can be considered as factors of the increase in resistance, but these are collectively referred to as the increase in resistance of the storage battery cell for the sake of simplicity.

Summarizing the above description, the deterioration modes of the storage battery cell roughly include at least four kinds of deterioration, that is, deterioration due to the positive electrode capacity, deterioration due to the negative electrode capacity, deterioration due to the lithium consumption, and deterioration due to the resistance of the storage battery cell.

In view of the above deterioration modes, the voltage function of the storage battery cell reflecting the deterioration parameter can be expressed as the following expression (36).

$${f}_{b} \left({s}_{0} ; \text{Φ}\right) = {f}_{p} \left({φ}_{p , 1} {s}_{0} + {φ}_{p , 2}\right) - {f}_{n} \left({φ}_{n , 1} {s}_{0} - {φ}_{n , 2}\right) + {φ}_{b} R I \qquad \text{[Expression 36]}$$

In the above expression (36), “s₀” is the normalized capacity of a reference storage battery, and “Φ” is the deterioration parameter. The deterioration parameter Φ is defined as Φ:= [φ_{p,1},φ_{p,2},φ_{n,1},φ_{n,2},φ_{b}]^{T}. Here, “φₚ,₁” represents a positive electrode capacity retention, and “φₚ,₂” represents a deviation of the positive electrode potential curve due to lithium consumption. In addition, “φ_{n,1}” represents a negative electrode capacity retention, and “φₙ,₂” represents at least one of a deviation of the negative electrode potential curve and an estimation error of the normalized capacity of the cell at the time of diagnosis. Moreover, “φ_{b}” represents a resistance increase rate.

At this time, an evaluation function for estimating the degree of deterioration of the storage battery 2 is expressed by the following expression (37).

$${J}_{d} \left(\text{Φ}\right) = {\sum }_{j = - {N}_{I}}^{{N}_{D}} {\sum }_{k = {k}_{0}}^{{k}_{f}} {w}_{j} {\left({V}_{0 , k}^{\left(j\right)} - {f}_{b}^{\left(j\right)} \left({s}_{0 , k} ; \text{Φ}\right)\right)}^{2} \qquad \text{[Expression 37]}$$

In the above expression (37), “V^{(j)}_{0,k}” is j-th order differential/integral voltage data at the discrete time “k” of certain reference storage battery data. There are various methods described above as a technique for minimizing an evaluation function J_{d} Here, only the deterioration parameter Φ is used as the estimated parameter, but a part of function parameters of “fb” may be included in the estimated parameter and simultaneously estimated. Note that the certain reference storage battery data is data of a storage battery having a different degree of deterioration. The certain reference storage battery data may be data of the same storage battery acquired at a different time. Also, instead of “V^{(j)}₀,ₖ”, a value calculated from a voltage function of the storage battery cell expressing “V^{(j)}_{0,k}” may be used.

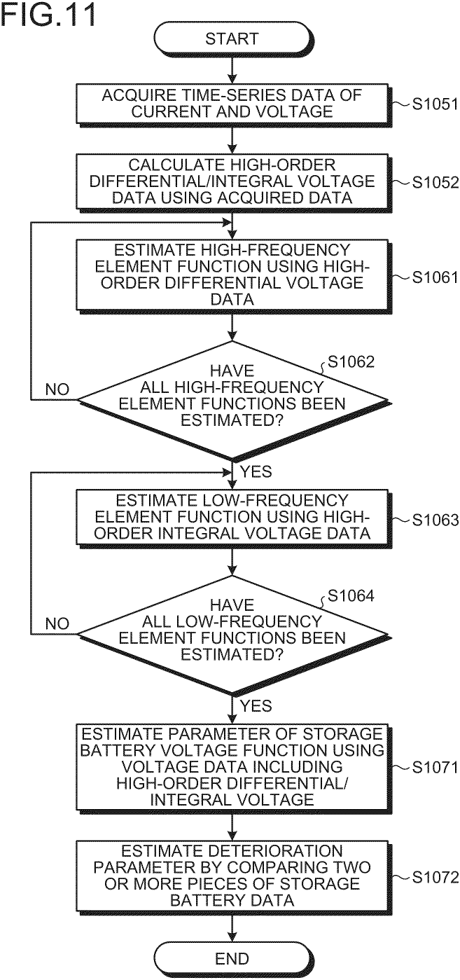

Next, a processing procedure by a storage battery internal state estimation method according to the first embodiment will be described with reference to FIG. 11. FIG. 11 is a flowchart illustrating an example of the processing procedure by the storage battery internal state estimation method according to the first embodiment.

First, in step S1051, the data generation unit 5 acquires time-series data of current and voltage. The time-series data of the current is acquired from the current detection device 3, and the time-series data of the voltage is acquired from the voltage detection device 4.

In the following step S1052, the data generation unit 5 calculates high-order differential/integral voltage data using the acquired data. The high-order differential/integral voltage data includes differential data up to an N_{D}-th order and integral data up to an N₁-th order normalized by the normalized capacity.

In the following step S1061, the separate estimation unit 6 estimates a high-frequency element function using the high-order differential voltage data of the high-order differential/integral voltage data.

In the following step S1062, it is checked whether or not all the high-frequency element functions have been estimated. If all the high-frequency element functions have not been estimated (No in step S1062), the procedure returns to the processing of step S1061 and repeats the processing of steps S1061 and S1062. If all the high-frequency element functions have been estimated (Yes in step S1062), the procedure proceeds to step S1063.

Note that, in the typical processing of step S1061, a step of estimating an element function including at least one higher high-frequency element function from data including higher high-order differential is repeated in order from higher high-order differential data to lower-order differential data. At the time of parameter estimation, a parameter of an approximate function approximating a function that has not yet been estimated may be simultaneously estimated, or a parameter of an element function estimated in the past may be used.

In the following step S1063, the separate estimation unit 6 estimates a low-frequency element function using the high-order integral voltage data of the high-order differential/integral voltage data.

In the following step S1064, it is checked whether or not all the low-frequency element functions have been estimated. If all the low-frequency element functions have not been estimated (No in step S1064), the procedure returns to the processing of step S1063 and repeats the processing of steps S1063 and S1064. If all the low-frequency element functions have been estimated (Yes in step S1064), the procedure proceeds to step S1071.

Note that, in the typical processing of step S1063, a step of estimating an element function including at least one lower low-frequency element function from data including higher high-order integral is repeated in order from higher high-order integral data to lower-order integral data. At the time of parameter estimation, a parameter of an approximate function approximating a function that has not yet been estimated may be simultaneously estimated, or a parameter of an element function estimated in the past including the high-frequency element function may be used.

In the following step S1071, the integrated estimation unit 7 estimates a parameter of a storage battery voltage function using the voltage data including the high-order differential/integral voltage. Typically, the parameter of the storage battery voltage function is estimated using the parameter of the element function estimated so far as an initial value of the parameter of the storage battery voltage function. Note that although the storage battery voltage function is typically expressed by a sum of element functions being the high-frequency element function or the low-frequency element function, there may be an element function that does not belong to either the high-frequency element function or the low-frequency element function. That is, there may be an element function whose parameter is not estimated in steps S1061 and S1063 and is estimated for the first time in step S1071.

In the final step S1072, the deterioration diagnosis unit 8 estimates a deterioration parameter by comparing two or more pieces of storage battery data. Specifically, a parameter including the deterioration parameter included in the storage battery voltage function is estimated such that an error with respect to the high-order differential voltage data of a reference storage battery is reduced.

Note that the order of the processing illustrated in FIG. 11 is an example and is not limited thereto. For example, the processing in steps S1061 and S1062 of repeating the estimation of the high-frequency element function and the processing in steps S1063 and S1064 of repeating the estimation of the low-frequency element function may be performed in the reverse order. Also, both sets of the processing are not necessarily required. In addition, there is no need to separately perform the estimation processing of the high-frequency element function and the estimation processing of the low-frequency element function each in one go. For example, after a certain high-frequency element function is subjected to separate estimation, a certain low-frequency element function may be estimated before another high-frequency element function is estimated.

### Second Embodiment

Hereinafter, a storage battery internal state estimation device and a storage battery internal state estimation method according to a second embodiment will be described. Note, however, that description of parts already described in the first embodiment will be omitted as appropriate.

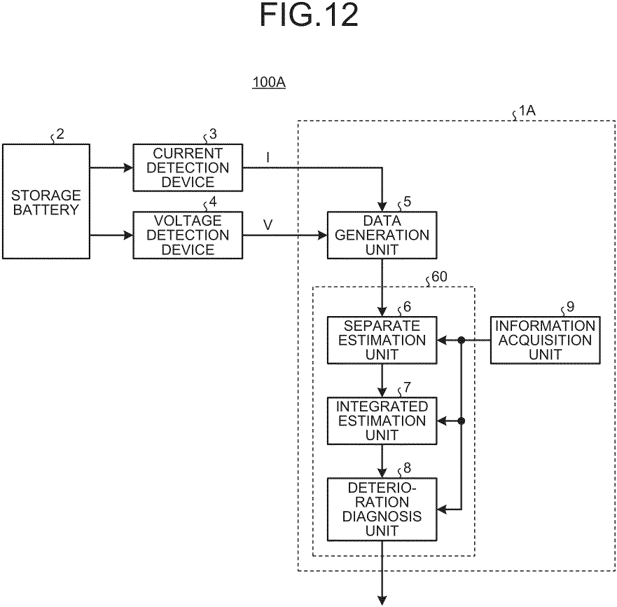

FIG. 12 is a diagram illustrating an example of a configuration of a storage battery deterioration diagnosis system 100A including a storage battery internal state estimation device 1A according to the second embodiment. The storage battery internal state estimation device 1A according to the second embodiment is obtained by adding an information acquisition unit 9 to the configuration of the storage battery internal state estimation device 1 according to the first embodiment illustrated in FIG. 1. The other components are identical or equivalent to those illustrated in FIG. 1 and are denoted by the same reference numerals as those assigned to such components in FIG. 1.

The separate estimation unit 6, the integrated estimation unit 7, and the deterioration diagnosis unit 8 of the second embodiment can perform the above-described processing using information related to the storage battery acquired from the information acquisition unit 9.

The information acquisition unit 9 acquires the information related to the storage battery 2 in advance. The information acquisition unit 9 provides the acquired information to the separate estimation unit 6, the integrated estimation unit 7, and the deterioration diagnosis unit 8 such that the acquired information can be used for deterioration diagnosis of the storage battery 2. The information here includes a relationship between an open circuit voltage and a charge amount of a reference storage battery, typically a new storage battery, a relationship between an open circuit potential of a positive electrode and a charge amount of the positive electrode, a used charge amount region of the positive electrode in a new storage battery cell, a relationship between an open circuit potential of a negative electrode and a charge amount of the negative electrode, a used charge amount region of the negative electrode in the new storage battery cell, and information on functions thereof. This information may also include information related to internal resistance of the positive electrode and the negative electrode. Furthermore, in a case where the active material of at least one of the positive electrode and the negative electrode is composed of a plurality of active materials, the above information may be held for each of the plurality of active materials. The information acquisition unit 9 may acquire the information from an external information source or may hold the information in advance.

When such information is held in advance, the detailed deterioration diagnosis of the storage battery 2 can be performed by fitting the voltage curve of the storage battery 2 or estimating parameters characterizing the deterioration for a differential voltage curve and a differential capacity curve by using, as variables, the charge amount, capacity retention, and internal resistance of the storage battery in each of a positive electrode potential curve and a negative electrode potential curve being held. This type of technique is disclosed in, for example, Japanese Patent No. 5889548 “Battery deterioration calculation device” or Patent Literature 1 described above, that is, Japanese Patent No. 6123844 “Secondary battery capacity measurement system and secondary battery capacity measurement method”.

However, as described above, it is not easy to collectively estimate a plurality of function parameters and deterioration parameters used for the voltage curve or the differential voltage curve. In addition, using only the voltage curve or the differential voltage curve can be advantageous for estimating a certain element function in terms of the SN ratio, but can be disadvantageous for estimating another element function. For example, in the voltage curve, it is difficult to see a steep potential change due to a phase change often derived from the negative electrode potential curve, whereas in the differential voltage curve, a gentle potential change often derived from the positive electrode potential curve and a component close to direct current due to internal resistance are attenuated. Moreover, the voltage curve at the time of charging and discharging is also affected by hysteresis according to a past charge-discharge history and the charge amount at the start of charging and discharging. In general, due to the influence of hysteresis, there is a gap between the open circuit voltage and the open circuit potential on the charge side and the open circuit voltage and the open circuit potential on the discharge side. Due to this gap, qualitatively, the curve gradually approaches the open circuit voltage and the open circuit potential on the charge side at the time of charging, and gradually approaches the open circuit voltage and the open circuit potential on the discharge side at the time of discharging. This directly affects the voltage curve.

Therefore, in the storage battery internal state estimation device 1A according to the present disclosure, the function parameters and the deterioration parameters are estimated while reducing the estimated parameters by appropriate separate estimation while improving the SN ratio. Then, the voltage curve of the storage battery 2 is fitted using not only the voltage data but also at least any of the high-order differential data and the high-order integral data. As a result, the high-frequency component or the low-frequency component of the voltage curve can be amplified or attenuated to be able to enhance the accuracy and stability of parameter estimation as described in the first embodiment. In addition, by using the high-order differential voltage data, the gradual asymptotic curve of the hysteresis is attenuated by the high-order differential so that the function parameters and the deterioration parameters are more easily estimated.

Note that in the configuration of the second embodiment, in a case where the information acquisition unit 9 holds the function parameters, at least one of the separate estimation unit 6 and the integrated estimation unit 7 can be omitted.

The configuration and operation of the storage battery internal state estimation device according to the first and second embodiments have been described above. In the first and second embodiments, the time-series data for estimation uses the high-order differential/integral of the voltage by the capacity, that is, the high-order differential/integral voltage obtained by differentiating or integrating the voltage with the capacity, but can use high-order differential/integral of the capacity by the voltage, that is, high-order differential/integral capacity obtained by differentiating or integrating the capacity with the voltage. Also, both the high-order differential/integral voltage and the high-order differential/integral capacity may be used. When the relationship between the voltage and the capacity is viewed on a high-order differential/integral voltage curve, there is an advantage that the positive and negative electrode potential curves are easily separated because the voltage can be expressed by a difference between the positive electrode potential and the negative electrode potential. On the other hand, when the relationship between the voltage and the capacity is viewed on a high-order differential/integral capacity curve, the horizontal axis represents the voltage so that, unlike the case of the high-order differential/integral voltage, even in a case where the normalized capacity has an error, it is not necessary to estimate the normalized capacity, but instead, it is sufficient to estimate an overvoltage due to internal resistance. Since the component to be amplified is different between the high-order differential/integral voltage and the high-order differential/integral capacity, there is a case where the estimation is performed more easily using one of the high-order differential/integral voltage and the high-order differential/integral capacity than using the other. For example, a first-order differential voltage dV/ds and a first-order differential capacity ds/dV have a reciprocal relationship and thus a complementary relationship in which a change is gradual in one and abrupt in the other. The parameter estimation can thus be facilitated by appropriate use of both for estimation. Specifically, an evaluation function expressed by the following expression (38) obtained by modifying the above expression (29) is used to minimize the evaluation function.

$$\begin{matrix}{J}_{0} \left(θ\right) = {\sum }_{j = - {N}_{I 1}}^{{N}_{D 1}} {\sum }_{k = k 01}^{{k}_{f 1}} {w}_{j} {\left({f}_{b}^{\left(j\right)} \left({s}_{k} ; θ\right) - {V}_{k}^{\left(j\right)}\right)}^{2} + \\ {\sum }_{j = - {N}_{I 2}}^{{N}_{D 2}} {\sum }_{k = {k}_{02}}^{{k}_{f 2}} {λ}_{j} {\left({f}_{b}^{- 1} \left({V}_{k} ; θ\right) - {s}_{k}^{\left(j\right)}\right)}^{2}\end{matrix} \qquad \text{[Expression 38]}$$

In the above expression (38), a sum of squares of errors related to the high-order differential/integral capacity is weighted by “λ” and added together. Note that “f_{b}^{-1(j)}” is a j-th order differential/integral of an inverse function s=f_{b}⁻¹(V)of a function V=f_{b}(s). The j-th order differential/integral f_{b}^{-1(j)} can be numerically calculated even when not analytically and explicitly obtained. Note that the high-order differential/integral capacity function may be expressed as s=f_{b}(V), and the high-order differential/integral voltage function may be obtained as its inverse function V=f_{b}⁻¹(s).The evaluation function in the estimation of the deterioration parameter is handled similarly.

Note that, without the above expression (38), a parameter estimated using either one of the high-order differential/integral voltage and the high-order differential/integral capacity may be used as an initial value, and the parameter may be re-estimated using the other or both of the high-order differential/integral voltage and the high-order differential/integral capacity. Alternatively, a capacity function and a voltage function may be separately formed as a sum of element functions, and parameters of both may be estimated using high-order differential/integral capacity data and high-order differential/integral voltage data.

Although the differential/integral voltage has been used in the above description, since the differential is included in a high-pass filter (HPF) and the integral is included in a low-pass filter (LPF), the processing may be performed in a more generalized manner using at least one of a plurality of HPFs and LPFs. In the case of this processing, the “higher-order differential” in the above description corresponds to a “HPF that further amplifies a higher frequency”. Likewise, the “higher-order integral” corresponds to a “LPF that further amplifies a lower frequency”. The use of at least one of the HPFs and the LPFs increases the degree of freedom, but a function that has been passed through the HPF and/or the LPF cannot be expressed by an elementary function in many cases. This increases the difficulty of optimization calculation in the parameter estimation and makes the calculation complicated.

Moreover, although the description has been made using the integer order differential/integral, in addition to or instead of the normal integer order differential/integral, a so-called fractional differential/integral, which is arithmetic processing including a non-integer order differential/integral, may be used. Using the fractional differential/integral enables more flexible extraction or attenuation of a specific element function. In this case as well, there are advantages and disadvantages similar to those in the case of using at least one of the HPFs and the LPFs.

The following expression (39) expresses a Cauchy’s formula representing fractional integral with “a” as a base point.

$${f}^{\left(- α\right)} \left(x\right) = \frac{1}{\left(α\right)} {\int }_{a}^{x} {\left(x - t\right)}^{α - 1} f \left(t\right) d t \qquad \text{[Expression 39]}$$

Using the Cauchy’s formula enables efficient calculation of the fractional integral. Using the Cauchy’s formula is efficient in the sense that, even in numerical calculation of n-th order integral, a value is obtained by performing integral calculation once according to the Cauchy’s formula without repeating integral calculation “n” times. Also, using the Cauchy’s formula enables calculation of the normal integer order integral using the same formula.

In the case of α-th order fractional differential, there are several definitions. For example, when “α” is a natural number n_{α} and is rewritten as α=n_{α}-β using a real number β that is 0<β<1, the calculation can be performed using the following expression (40).

$${f}^{α} \left(x\right) = \frac{1}{\text{Γ} \left(β\right)} {\int }_{a}^{x} {\left(x - t\right)}^{β - 1} {f}^{{n}_{α}} \left(t\right) d t \qquad \text{[Expression 40]}$$

The above expression (40) is an expression called Caputo differential. In a case where the above expression (40) is used, an operation of β-th order fractional integral is performed on a function obtained by n_{α}-th integer order differential.

Note that, as a formulation method and a calculation method of the fractional differential/integral, knowledge of known fractional calculus can be used. Also, in a case where the above expressions (39) and (40) cannot be strictly calculated such as in a case where an integral result of a function cannot be obtained explicitly or in a case where time-series data is differentiated/integrated, various known approximate differentiation and approximate integration as described in the first embodiment can be used. Furthermore, a filtering technique or the like can also be used to remove noise at the time of differentiation.

Finally, the effectiveness related to the technique disclosed in the present description, that is, the effect of using the technique disclosed in the present description will be described. Note that in the following description, “fractional differential” also includes “integer order differential”, and “fractional integral” also includes “integer order integral”.

In a case where “fractional differential” is used for a voltage curve, time-series data for estimation includes Z_{DJ}-th (j=1,..., N_{D}) order differential voltage curves, the number of which is “N_{D}” that is an integer of one or more. Here, “Z_{Dj}” is a positive real number, and Z_{Dk}≠1 for at least one “k”. Moreover, in a case where “fractional integral” is used for a voltage curve, time-series data for estimation includes Z_{Ij}-th (j=1,..., N_{I}) order integral voltage curves, the number of which is “N_{I}” that is an integer of one or more. Here, “Z_{Ij}” is a positive real number.

(1) In a case where fractional differential is used for a voltage curve, an SN ratio of a high-frequency component included in the voltage curve can be improved by attenuating a low-frequency component while amplifying the high-frequency component of the voltage curve derived from characteristics such as a phase change of an electrode material. This facilitates estimation of a model function of a battery. In addition, using not only the voltage curve but also a fractional differential curve enables more accurate checking of the validity of the result of estimation. For example, it is fully possible for an estimation failure to occur in which a model function having a small error with respect to the voltage curve has a large error with respect to the fractional differential voltage curve.

(2) In a case where fractional integral is used for a voltage curve, an SN ratio of a low-frequency component included in the voltage curve can be improved by attenuating a high-frequency component while amplifying the low-frequency component of the voltage curve derived from characteristics such as a phase change of an electrode material. This facilitates estimation of a model function of a storage battery. Moreover, as with (1), the validity of the result of estimation can be checked more accurately.

(3) In a case where both fractional differential and fractional integral are used for a voltage curve, an SN ratio of a high-frequency component can be improved in a fractional differential voltage curve, and an SN ratio of a low-frequency component can be improved in a fractional integral curve. The improvement of both of the SN ratios further facilitates estimation of a model function of a battery. Moreover, as with (1) and (2), the validity of the result of estimation can be checked more accurately. Furthermore, since both fractional differential and fractional integral are used, it is possible to obtain more detailed information regarding the result of estimation such as which component of the low-frequency component and the high-frequency component has failed to be estimated.

(4) In a case where fractional differential is used for a capacity curve as well, an effect similar to that of the above (1) can be obtained.

In a case where fractional integral is used for a capacity curve as well, an effect similar to that of the above (2) can be obtained.

In a case where both fractional differential and fractional integral are used for a capacity curve as well, an effect similar to that of the above (3) can be obtained.

In a case where “fractional differential” is used for a capacity curve, time-series data for estimation includes Z_{Dj}-th (j=1,..., N_{D}) order differential capacity curves, the number of which is “N_{D}” that is an integer of one or more. Here, “Z_{Dj}” is a positive real number, and Z_{Dk}≠1 for at least one “k”. Moreover, in a case where “fractional integral” is used for a capacity curve, time-series data for estimation includes Z_{Ij}-th (j=1,..., N_{I}) order integral capacity curves, the number of which is “N_{I}” that is an integer of one or more. Here, “Z_{Ij}” is a positive real number.

(7) In a case where both fractional differential and fractional integral are used for both a voltage curve and a capacity curve, the voltage curve, the capacity curve, and the fractional differential/integral curves thereof have advantages and disadvantages in estimating a model function as described above. Therefore, if the case of using fractional differential/integral for the voltage curve and the case of using fractional differential/integral for the capacity curve are appropriately adopted in consideration of the advantages and disadvantages, even a parameter that is difficult to estimate when only one of the cases is adopted can be estimated accurately.

In addition, when both fractional differential and fractional integral are used for both the voltage curve and the capacity curve, time-series data for estimation includes Z_{D1j}-th (j=1,..., N_{D1}) order differential voltage curves, the number of which is “N_{D1}” that is an integer of one or more, Z_{D2j}-th (j=1,..., N_{D2}) order differential capacity curves, the number of which is “N_{D2}” that is an integer of one or more, Z_{I1j}-th (j=1,..., N_{I1}) order integral voltage curves, the number of which is “N_{I1}” that is an integer of one or more, and Z_{I2j}-th (j=1,..., N_{I2}) order integral capacity curves, the number of which is “N_{I2}” that is an integer of one or more. Here, “Z_{D1j}”, “Z_{D2j}”, “Z_{I1j}”, and “Z_{I2j}” are positive real numbers, “Z_{D1j}” satisfies Z_{D1k}≠1 for at least one “k”, and “Z_{D2j}” satisfies Z_{D2k}≠1 for at least one “k”.

(8) In any one of the above (1) to (7), furthermore, a deterioration parameter of the storage battery may be estimated by relative comparison with time-series data of one or more integer number of storage batteries acquired in the past. As a result, deterioration diagnosis can be performed without holding relational data between an electrode potential and an electrode capacity or the like in advance.

(9) Moreover, in any one of the above (1) to (7), deterioration diagnosis can be performed in a case where relational data between an electrode potential and an electrode capacity or the like is held in advance. In the case of this example, the SN ratio of at least one of the high-frequency component and the low-frequency component included in the data can be improved by an amount corresponding to use of at least any of data of an original curve or a Z-th order differential curve other than a first-order differential curve and a Z-th order integral curve. As a result, the estimation accuracy and the stability of the estimation calculation can be improved, and the probability of convergence to an optimal value can be increased.

(10) Moreover, in any one of the above (1) to (7), the model function may be represented as a sum of element functions. This enables separate estimation such as estimating a relatively high-frequency element function from fractional differential data and estimating a relatively low-frequency element function from fractional integral data. This attenuates a component not to be estimated and amplifies a component to be estimated while reducing the number of parameters to be estimated at a time, thereby facilitating estimation of the model function.

(11) In the above (10), furthermore, a function including a position parameter µ and a scale parameter σ may be used for each of the high-frequency element function and the low-frequency element function. This facilitates assignment of the element function to a specific component extracted by fractional differential/integral, and also clarifies a relationship between an order “Z” of Z-th order differential/integral and a level of amplification or a level of attenuation of the element function as in expression (26). This facilitates separate estimation of the element functions.

(12) In the above (11), furthermore, a skew sigmoid function expressed by the above expression (13) or a skew peak function expressed by the above expression (14) may be used for at least one of the high-frequency element function and the low-frequency element function. This allows the element function to be modeled with high accuracy in a form that is easy to handle in practical use.

(13) In any one of the above (10) to (12), furthermore, an operation of estimating the high-frequency element function of a higher frequency using a Z-th order differential curve of a higher order may be repeated in order, and an operation of estimating the low-frequency element function of a lower frequency using a Z-th order integral curve of a higher order may be repeated in order. Then, the high-frequency element function and low-frequency element function already estimated may be subtracted when a certain high-frequency element function or low-frequency element function is estimated. This allows the element function to be estimated by emphasizing the high-frequency or low-frequency component one by one in order by high-order differential/integral without collectively estimating all the element functions. In addition, at the time of estimation, the influence of a higher-frequency component or a lower-frequency component is removed by the use of the past estimation result, so that the estimation is facilitated. Then, in addition to the time-series data for estimation, parameters of the estimated high-frequency element function and low-frequency element function are used as initial values of estimation, for example, and the model function of the storage battery is estimated again. As a result, the estimation can be started from a parameter value with a high probability of being close to the optimal value, and a highly accurate estimated value of the parameter can be obtained.

(14) Moreover, in any one of the above (10) to (12), the estimation may be performed by replacing the element function that has not yet been estimated, particularly the element function attenuated by high-order differential/integral, with an approximate function. This facilitates the estimation of the element function to be estimated. This processing reduces the number of parameters as compared to a case where the attenuated element function is simultaneously estimated as it is without being replaced with the approximate function, and in contrast obtains a more accurate model due to the use of the approximate function as compared to a case where only the element function to be estimated is estimated. Therefore, the parameter can be estimated with higher accuracy.

(15) In any one of the above (10) to (14), furthermore, the high-frequency element function may be used for one electrode function, and the low-frequency element function may be used for another electrode function. As a result, the estimation of the high-frequency element function by the fractional differential data estimates the one electrode function, and the estimation of the low-frequency element function by the fractional integral data estimates the other electrode function, so that a positive electrode function and a negative electrode function can be separately estimated.

(16) In the above (15), furthermore, for a storage battery in which a negative electrode includes graphite, the negative electrode function can be estimated from the fractional differential data and the positive electrode function can be estimated from the fractional integral data by using the low-frequency element function for the positive electrode function and the high-frequency element function for the negative electrode function. Here, the fact that a curve representing a relationship between an electrode potential and an electrode capacity of graphite can be modeled by a sum of the high-frequency element functions is used.

(17) In the estimation of the model function in the above (14), furthermore, an operation of estimating the high-frequency element function of a higher frequency using the fractional differential data of a higher order may be repeated, and an operation of estimating the low-frequency element function of a lower frequency using the fractional integral data of a higher order may be repeated. As a result, in the estimation of a certain element function, it is possible to estimate only a smaller number of parameters in one estimation while removing a component corresponding to the element function of a higher frequency or lower frequency from the time-series data. This further facilitates the estimation of the parameters.

(18) In the estimation of the model function in the above (14) or (17), after each element function is estimated, the parameter of the model function may be estimated again by, for example, using a parameter of each element function estimated as an initial value on the basis of the time-series data for estimation and the parameter of each element function estimated. As a result, the estimation can be started from a parameter value with a high probability of being close to the optimal value, and a more accurate estimated value of the parameter can be obtained.

Note that the configurations illustrated in the above embodiments merely illustrate an example so that another known technique can be combined, the embodiments can be combined together, or the configurations can be partially omitted and/or modified without departing from the scope of the present disclosure.

### REFERENCE SIGNS LIST

1, 1A storage battery internal state estimation device; 2 storage battery; 3 current detection device; 4 voltage detection device; 5 data generation unit; 6 separate estimation unit; 7 integrated estimation unit; 8 deterioration diagnosis unit; 9 information acquisition unit; 40 controller; 60 estimation unit; 100, 100A storage battery deterioration diagnosis system; 400 processor; 401 storage.

1-20. (canceled)

21. A storage battery internal state estimation device that estimates an internal state of a storage battery, the storage battery internal state estimation device comprising:
a data generation circuitry to generate time-series data for estimation from time-series data of a current value and a voltage value acquired from the storage battery; and
an estimation circuitry to estimate a model function of the storage battery on the basis of the time-series data for estimation, wherein
the time-series data for estimation includes at least one of:
Z Dvj-th (j=1,..., N Dv ) order differential voltage curves, the number of which is “N Dv” that is an integer of one or more;
Z Ivj-th (j=1,..., N Iv ) order integral voltage curves, the number of which is “N Iv” that is an integer of one or more;
Z Dqj-th (j= 1,..., N Dq ) order differential capacity curves, the number of which is “N Dq” that is an integer of one or more; and
Z Iqj-th (j=1..... N Iq ) order integral capacity curves, the number of which is “N Iq” that is an integer of one or more,
the model function is represented by a sum of element functions including a high-frequency element function and a low-frequency element function, and
the estimation circuitry
estimates at least the high-frequency element function from the Z Dvj -th order differential voltage curve or the Z Dqj -th order differential capacity curve, and
estimates at least the low-frequency element function from the Z Ivj -th order integral voltage curve or the Z Iqj -th order integral capacity curve.

22. The storage battery internal state estimation device according to claim 21, wherein
at least one of the high-frequency element function includes a position µ and a scale σ as parameters, and
at least one of the low-frequency element function includes a position µ and a scale σ as parameters.

23. The storage battery internal state estimation device according to claim 22, wherein
when “x” is a capacity of the storage battery, F(x; 1,µ,σ) is an arbitrary sigmoid function having the position µ and the scale σ as the parameters, and f(x; 1,µ,σ) is a peak function obtained by differentiating the sigmoid function, at least one of the high-frequency element function and the low-frequency element function is a skew sigmoid function expressed by the following expression (1) using a height “k” and a skew parameter “v”, or a skew peak function expressed by the following expression (2) obtained by differentiating the skew sigmoid function:
$${f}_{s k e w} \left(x ; k , μ , σ , v\right) = \frac{k}{1 - exp \left(- v\right)} \left(1 - exp \left(- v F \left(x ; 1 , μ , σ\right)\right)\right) \qquad \text{[Expression 1]}$$
$$\begin{matrix}{f}_{s k e w}^{\left(1\right)} \left(x ; k , μ , σ , v\right) = \\ \frac{k}{1 - exp \left(- v\right)} v f \left(x ; 1 , μ , σ\right) e x p \left(- v F \left(x ; 1 , μ , σ\right)\right)\end{matrix} \qquad \text{[Expression 2]}$$
.

24. The storage battery internal state estimation device according to claim 21, wherein
the estimation circuitry
repeats in order an operation of estimating the high-frequency element function of a higher frequency using the Z_{Dj}-th order differential voltage curve or the Z_{Dj}-th order differential capacity curve of a higher order,
repeats in order an operation of estimating the low-frequency element function of a lower frequency using the Z_{Ij}-th order integral voltage curve or the Z_{Ij}-th order integral capacity curve of a higher order,
estimates the high-frequency element function or the low-frequency element function using the high-frequency element function and the low-frequency element function that have already been estimated, and
estimates the model function on the basis of the time-series data for estimation and the high-frequency element function and the low-frequency element function estimated.

25. The storage battery internal state estimation device according to claim 21, wherein
the estimation circuitry
when estimating the high-frequency element function using the Z_{Dj}-th order differential voltage curve or the Z_{Dj}-th order differential capacity curve, simultaneously estimates an approximate function that approximates the element function that has not yet been estimated other than the high-frequency element function to be estimated, and
when estimating the low-frequency element function using the Z_{Ij}-th order integral voltage curve or the Z_{Ij}-th order integral capacity curve, simultaneously estimates an approximate function that approximates the element function that has not yet been estimated other than the low-frequency element function to be estimated.

26. A storage battery internal state estimation method that estimates an internal state of a storage battery, the storage battery internal state estimation method comprising:
generating time-series data for estimation from time-series data of a current value and a voltage value acquired from the storage battery; and
estimating a model function of the storage battery on the basis of the time-series data for estimation, wherein
the time-series data for estimation includes at least one of:
Z Dvj-th (j=1...., N Dv ) order differential voltage curves, the number of which is “N Dv” that is an integer of one or more:
Z Ivj-th (j=1,..., N Iv ) order integral voltage curves, the number of which is “N Iv” that is an integer of one or more;
Z Dqj-th (j=1,..., N Dq ) order differential capacity curves, the number of which is “N Dq” that is an integer of one or more; and
Z Iqj-th (j=1,..., N Iq ) order integral capacity curves, the number of which is “N Iq” that is an integer of one or more,
the model function is represented by a sum of element functions including a high-frequency element function and a low-frequency element function, and
estimating the model function comprises:
estimating at least the high-frequency element function from the Z Dvj -th order differential voltage curve or the Z Dqj -th order differential capacity curve; and
estimating at least the low-frequency element function from the Z Ivj -th order integral voltage curve or the Z Iqj -th order integral capacity curve.

27. The storage battery internal state estimation method according to claim 26, wherein
at least one of the high-frequency element function includes a position µ and a scale σ as parameters, and
at least one of the low-frequency element function includes a position µ and a scale σ as parameters.

28. The storage battery internal state estimation method according to claim 27, wherein
when “x” is a capacity of the storage battery, F(x; 1,µ,σ) is an arbitrary sigmoid function having the position µ and the scale σ as the parameters, and f(x;1,µ,σ) is a peak function obtained by differentiating the sigmoid function, at least one of the high-frequency element function and the low-frequency element function is a skew sigmoid function expressed by the following expression (1) using a height “k” and a skew parameter “v”, or a skew peak function expressed by the following expression (2) obtained by differentiating the skew sigmoid function:
$${f}_{s k e w} \left(x ; k , μ , σ , v\right) = \frac{k}{1 - exp \left(- v\right)} \left(1 - exp \left(- v F \left(x ; 1 , μ , σ\right)\right)\right) \qquad \text{[Expression 1]}$$
$$\begin{matrix}{f}_{s k e w}^{\left(1\right)} \left(x ; k , μ , σ , v\right) = \\ \frac{k}{1 - exp \left(- v\right)} v f \left(x ; 1 , μ , σ\right) e x p \left(- v F \left(x ; 1 , μ , σ\right)\right)\end{matrix} \qquad \text{[Expression 2]}$$
.

29. The storage battery internal state estimation method according to claim 26, wherein
estimating the model function comprises:
repeating in order an operation of estimating the high-frequency element function of a higher frequency using the Z_{Dj}-th order differential voltage curve or the Z_{Dj}-th order differential capacity curve of a higher order;
repeating in order an operation of estimating the low-frequency element function of a lower frequency using the Z_{Ij}-th order integral voltage curve or the Z_{Ij}-th order integral capacity curve of a higher order;
estimating the high-frequency element function or the low-frequency element function using the high-frequency element function and the low-frequency element function that have already been estimated; and
estimating the model function on the basis of the time-series data for estimation and the high-frequency element function and the low-frequency element function estimated.

30. The storage battery internal state estimation method according to claim 26, wherein
estimating the model function comprises:
when estimating the high-frequency element function using the Z_{Dj}-th order differential voltage curve or the Z_{Dj}-th order differential capacity curve, simultaneously estimating an approximate function that approximates the element function that has not yet been estimated other than the high-frequency element function to be estimated; and
when estimating the low-frequency element function using the Z_{Ij}-th order integral voltage curve or the Z_{Ij}-th order integral capacity curve, simultaneously estimating an approximate function that approximates the element function that has not yet been estimated other than the low-frequency element function to be estimated.
